(19) United States
(12) Patent Application Publication
(10) Pub. No.: US 2024/0105560 A1
(43) Pub. Date: Mar. 28, 2024

(54) SEMICONDUCTOR DEVICE AND MANUFACTURING METHOD OF SEMICONDUCTOR DEVICE

(71) Applicant: ROHM CO., LTD., Kyoto-shi (JP)

(72) Inventors: Yasuhiro TAHARA, Kyoto-shi (JP); Soichiro TAKAHASHI, Kyoto-shi (JP)

(21) Appl. No.: 18/528,213

(22) Filed: Dec. 4, 2023

Related U.S. Application Data
(63) Continuation of application No. PCT/JP2022/024547, filed on Jun. 20, 2022.

(30) Foreign Application Priority Data
Jul. 13, 2021 (JP) 2021-115861

(51) Int. Cl. H01L 23/495; H01L 23/00

(52) U.S. Cl. CPC H01L 23/49551; H01L 23/49568; H01L 24/84; H01L 2224/84186; H01L 2224/84205; H01L 2924/351

(57) ABSTRACT

A semiconductor device includes: two conductive members; a semiconductor element bonded to one of the two conductive members; and a relay terminal bonded to the two conductive members. The relay terminal has a first strip portion and a second strip portion that are bonded to the two conductive members, and a connecting portion that connects the first strip portion and the second strip portion. The first strip portion has a first side. The connecting portion has a first intermediate side, and a first connecting side connecting the first side and the first intermediate side. As viewed in the thickness direction, the first connecting side is located away from a first virtual intersection that is an intersection of a first virtual line overlapping with the first side and a second virtual line overlapping with the first intermediate side.

### TECHNICAL FIELD

The present disclosure relates to a semiconductor device and a manufacturing method thereof, where the semiconductor device includes two conductive members that are adjacent to each other and a relay terminal bonded to the two conductive members by ultrasonic vibrations.

### BACKGROUND ART

JP-A-2013-235882 discloses an example of a semiconductor device including a plurality of terminals. The plurality of terminals are bonded by ultrasonic vibrations to a substrate on which a circuit is formed. This electrically connects the substrate and the plurality of terminals. Bonding with ultrasonic vibrations is more suitable than solder bonding when a relatively large current is supplied to a bonging target.

In a case where the target for bonding with ultrasonic vibrations is a flat conductive member, the bending rigidity of the conductive member is relatively small. As a result, a relatively large repeated stress acts on the conductive member due to ultrasonic vibrations, and stress concentration associated with the repeated stress occurs in the conductive member. This may cause cracks in the conductive member. Cracks formed in the conductive member increase the electric resistance of the conductive member, which causes an increase in the loss of the electric power supplied to the semiconductor device.

### BRIEF DESCRIPTION OF THE DRAWINGS

FIG. 1 is a perspective view illustrating a semiconductor device according to a first embodiment of the present disclosure.

FIG. 2 is a plan view illustrating the semiconductor device of FIG. 1.

FIG. 3 is a plan view corresponding to FIG. 2, with a top plate shown transparent.

FIG. 4 is a front view illustrating the semiconductor device of FIG. 1.

FIG. 5 is a right-side view illustrating the semiconductor device of FIG. 1.

FIG. 6 is a left-side view illustrating the semiconductor device of FIG. 1.

FIG. 7 is a bottom view illustrating the semiconductor device of FIG. 1.

FIG. 8 is a partially enlarged view of FIG. 3, illustrating a portion in a first sense of a first direction.

FIG. 9 is a partially enlarged view of FIG. 3, illustrating a portion in a second sense of the first direction.

FIG. 10 is a partially enlarged view of FIG. 3, illustrating a central portion.

FIG. 11 is a cross-sectional view taken along line XI-XI in FIG. 3.

FIG. 12 is a cross-sectional view taken along line XII-XII in FIG. 3.

FIG. 13 is a cross-sectional view taken along line XIII-XIII in FIG. 3.

FIG. 14 is a partially enlarged view of FIG. 10.

FIG. 15 is a partially enlarged view of FIG. 14, illustrating a portion in the first sense of the first direction.

FIG. 16 is a partially enlarged view of FIG. 14, illustrating a portion in the second sense of the first direction.

FIG. 17 is a cross-sectional view illustrating a method for bonding a relay terminal shown in FIG. 14.

FIG. 18 is a partially enlarged view of FIG. 8, illustrating a first semiconductor element and an area around the first semiconductor element.

FIG. 19 is a partially enlarged view of FIG. 8, illustrating a second semiconductor element and an area around the second semiconductor element.

FIG. 20 is a circuit diagram illustrating the semiconductor device of FIG. 1.

FIG. 21 is a partially enlarged plan view illustrating a first variation of the semiconductor device of FIG. 1.

FIG. 22 is a partially enlarged plan view illustrating a second variation of the semiconductor device of FIG. 1.

FIG. 23 is a partially enlarged plan view illustrating a semiconductor device according to a second embodiment of the present disclosure.

FIG. 24 is a partially enlarged plan view illustrating a manufacturing process of the semiconductor device shown in FIG. 23.

FIG. 25 is a partially enlarged plan view illustrating a manufacturing process of the semiconductor device shown in FIG. 23.

FIG. 26 is a partially enlarged plan view illustrating a manufacturing process of the semiconductor device shown in FIG. 23.

FIG. 27 is a partially enlarged plan view illustrating a manufacturing process of the semiconductor device shown in FIG. 23.

FIG. 28 is a partially enlarged plan view illustrating a manufacturing process of the semiconductor device shown in FIG. 23.

### DETAILED DESCRIPTION OF EMBODIMENTS

Embodiments of the present disclosure will be described with reference to the accompanying drawings.

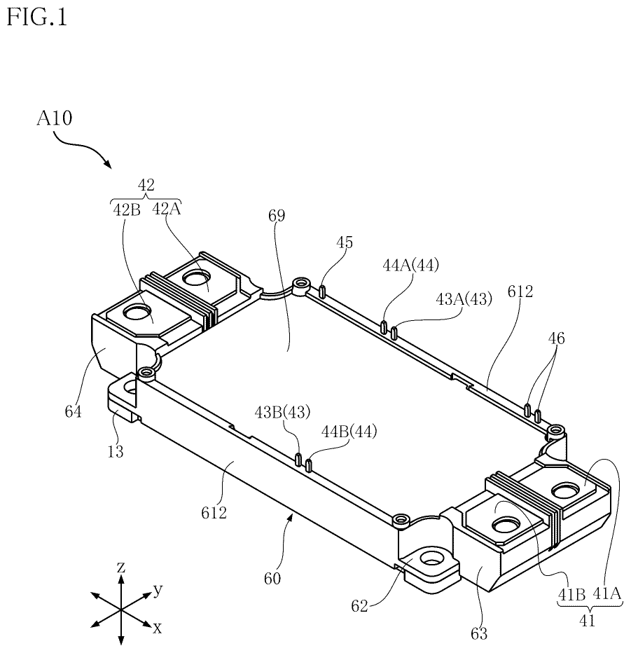

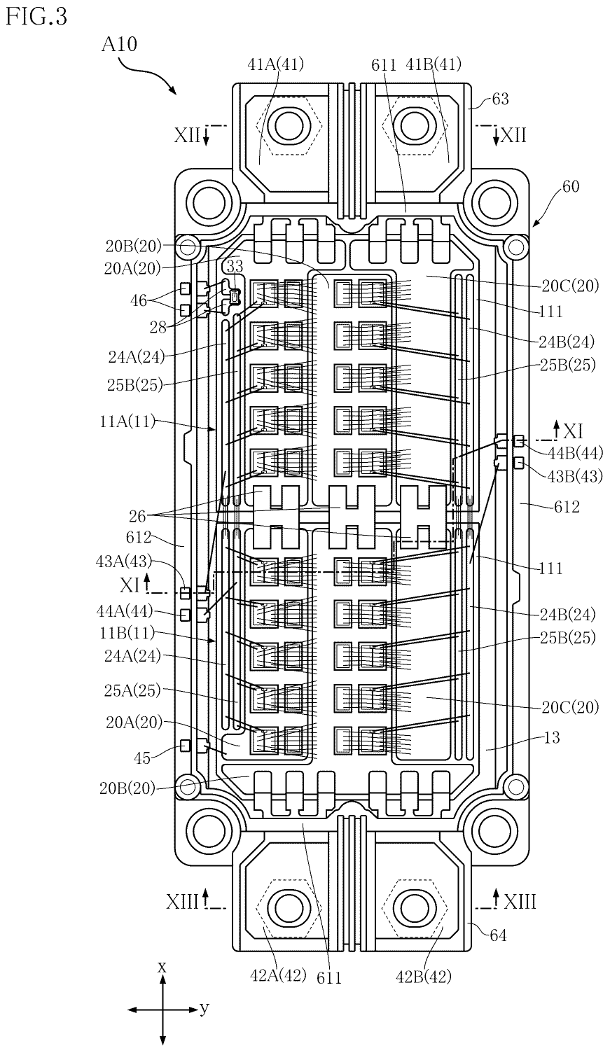

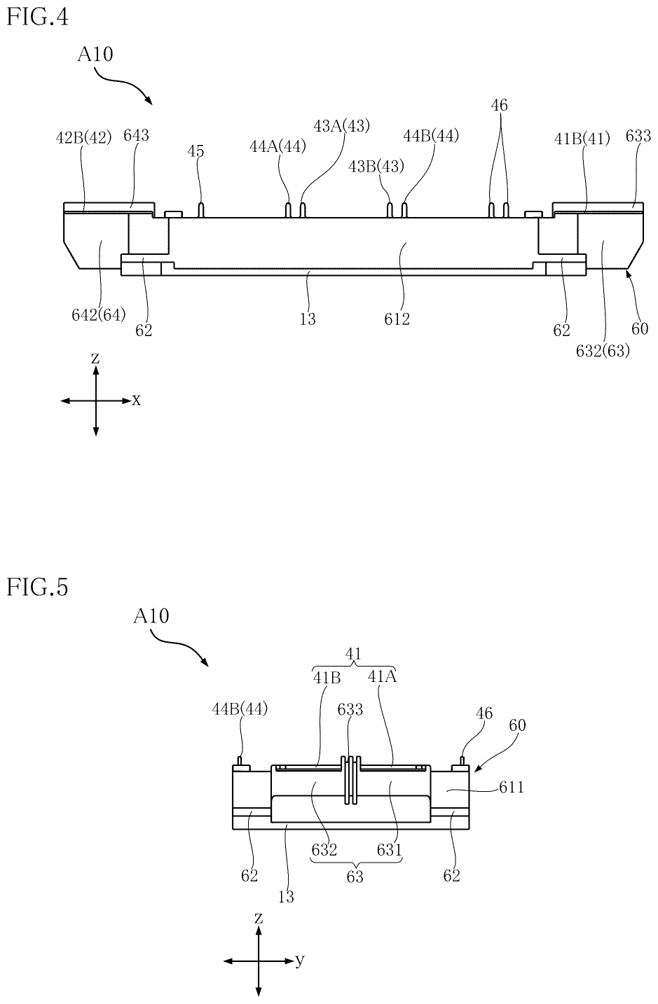

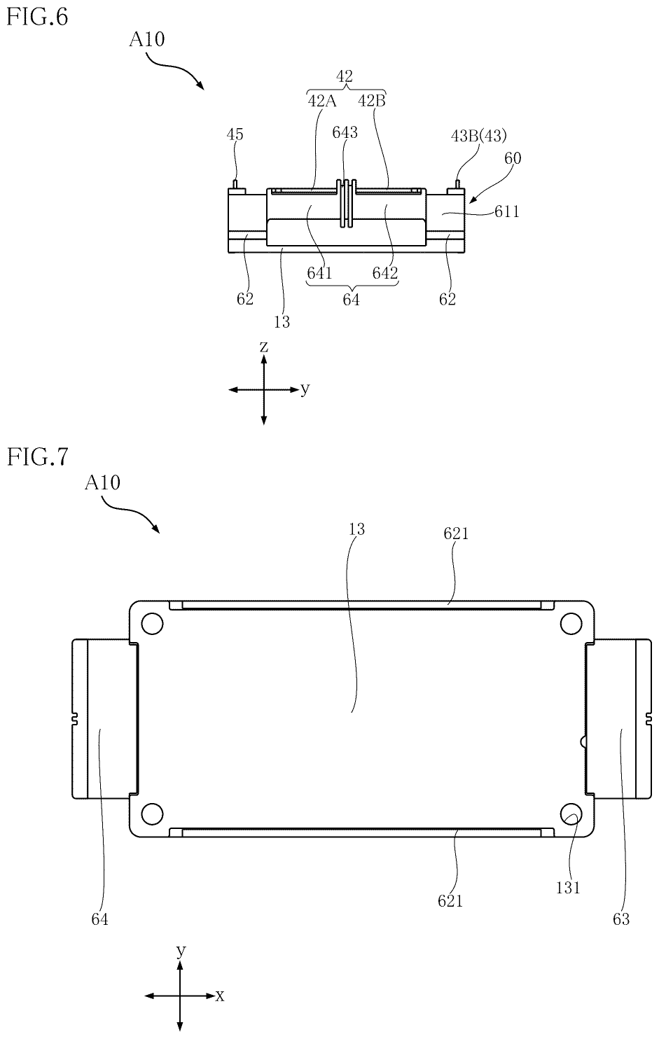

The following describes a semiconductor device A10 according to a first embodiment of the present disclosure, with reference to FIGS. 1 to 19. The semiconductor device A10 includes a plurality of base members 11, a plurality of conductive members 20, a plurality of input terminals 41, an output terminal 42, a plurality of relay terminals 26, and a plurality of semiconductor elements 31. Furthermore, the semiconductor device A10 includes a plurality of gate wiring lines 24, a plurality of detection wiring lines 25, a plurality of gate terminals 43, a plurality of detection terminals 44, a plurality of diodes 32, a heat dissipator 13, and a case 60. FIG. 3 and FIGS. 8 to 11 each show a top plate 69 in phantom for convenience of understanding. In FIG. 3, line XI-XI is indicated by a single-dot chain line.

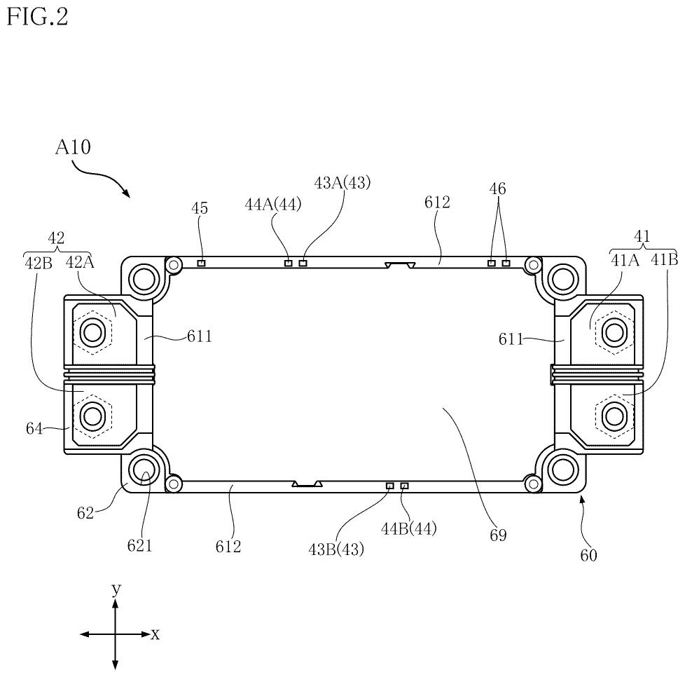

The semiconductor device A10 shown in FIG. 1 is a power module. The semiconductor device A10 is used in an inverter for any of various electronic products and hybrid vehicles. As shown in FIGS. 1 and 2, the semiconductor device A10 has a rectangular (or substantially rectangular) shape, as viewed in a thickness direction z. The thickness direction z refers to the direction along the thickness of a plurality of first conductive members 20A. For convenience of explanation, a direction perpendicular to the thickness direction z is referred to as a first direction x. The direction perpendicular to both the thickness direction z and the first direction x is referred to as a second direction y. The first direction x is the longitudinal direction of the semiconductor device A10.

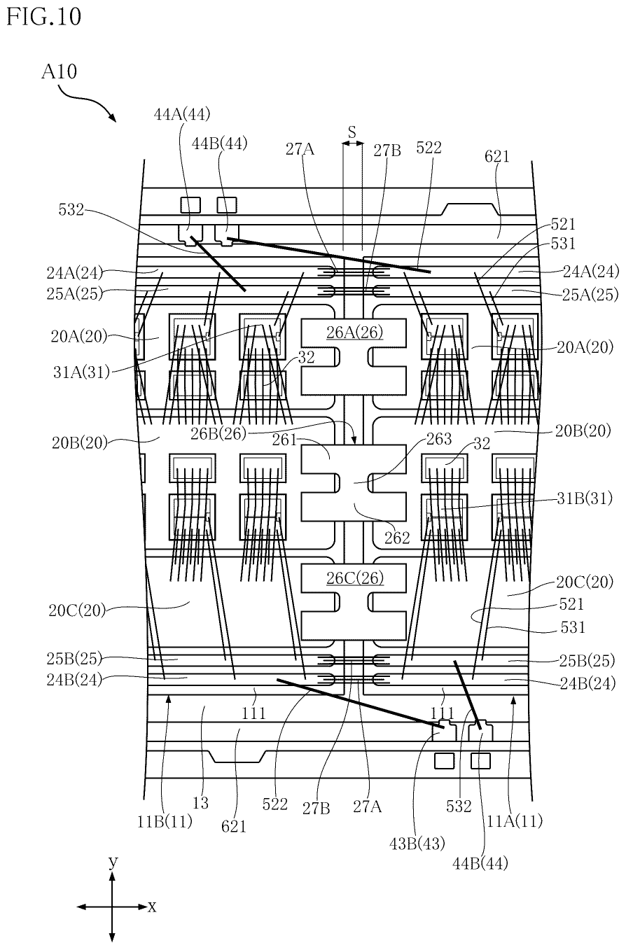

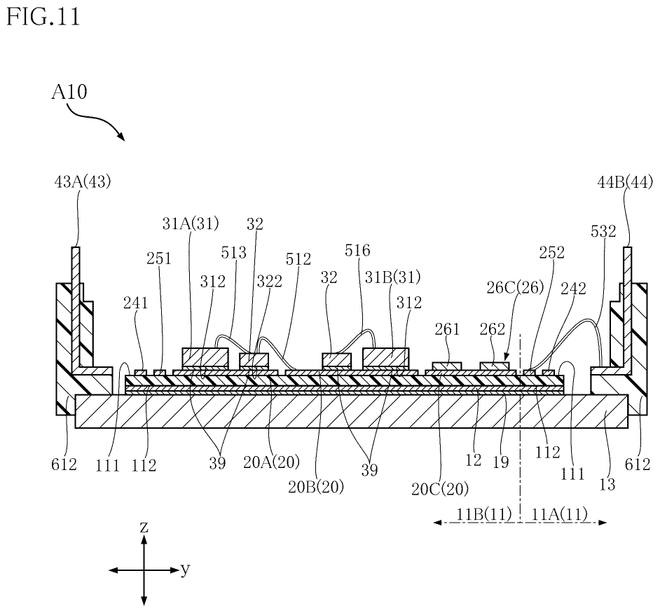

As shown in FIG. 11, the base members 11 are electrically insulating members supported by the heat dissipator 13. The base members 11 of the semiconductor device A10 include two base members 11 adjacent to each other in the first direction x. In the description of the semiconductor device A10, the two base members 11 are referred to as a first base member 11A and a second base member 11B, respectively. Although a plurality of base members 11 are provided in the example of the semiconductor device A10, it is possible to provide a single base member 11 in another example. Each of the first base member 11A and the second base member 11B has an obverse surface 111 and a reverse surface 112 that face away from each other in the thickness direction z. As shown in FIG. 10, there is a gap S provided between the first base member 11A and the second base member 11B.

The base members 11 are made of a material containing a ceramic having a relatively high thermal conductivity. Such ceramic may be aluminum nitride (AlN). The base members 11 may be made with the use of direct bonded copper (DBC) substrates. Each of the DBC substrates is a substrate containing aluminum nitride with copper (Cu) foil bonded directly to both surfaces of the substrate in the thickness direction z.

As shown in FIG. 3, each of the conductive members 20 is provided on the obverse surface 111 of one of the base members 11. The conductive members 20 include a plurality of first conductive members 20A, a plurality of second conductive members 20B, and a plurality of third conductive members 20C. The composition of the conductive members 20 includes copper. When the DBC substrates are used as the base members 11, the conductive members 20 can be easily formed by patterning the copper foil bonded to the obverse surfaces 111. The surfaces of the conductive members 20 may be plated with silver (Ag).

As shown in FIG. 3, the first conductive members 20A include two first conductive members 20A adjacent to each other in the first direction x. The first conductive members 20A are arranged on the obverse surfaces 111 of the respective base members 11 (the first base member 11A and the second base member 11B). The second conductive members 20B include two second conductive members 20B adjacent to each other in the first direction x, and are located next to the first conductive members 20A in the second direction y. The second conductive members 20B are arranged on the obverse surfaces 111 of the respective base members 11. The third conductive members 20C include two third conductive members 20C adjacent to each other in the first direction x, and are located opposite from the first conductive members 20A with the second conductive members 20B therebetween in the second direction y. The third conductive members 20C are arranged on the obverse surfaces 111 of the respective base members 11.

As shown in FIG. 3, the gate wiring lines 24 are arranged on the obverse surfaces 111 of the base members 11. The gate wiring lines 24 include a plurality of first gate wiring lines 24A and a plurality of second gate wiring lines 24B. The first gate wiring lines 24A are arranged on the respective base members 11, and are adjacent to each other in the first direction x. The first gate wiring lines 24A are arranged in proximity to the first conductive members 20A in the second direction y. The second gate wiring lines 24B are arranged on the respective base members 11, and are adjacent to each other in the first direction x. The second gate wiring lines 24B are arranged in proximity to the third conductive members 20C in the second direction y.

As shown in FIG. 3, the detection wiring lines 25 are arranged on the obverse surfaces 111 of the base members 11. The detection wiring lines 25 include a plurality of first detection wiring lines 25A and a plurality of second detection wiring lines 25B. The first detection wiring lines 25A are arranged on the respective base members 11, and are adjacent to each other in the first direction x. The first detection wiring lines 25A are positioned between the first conductive members 20A and the first gate wiring lines 24A in the second direction y. The second detection wiring lines 25B are arranged on the respective base members 11, and are adjacent to each other in the first direction x. The second detection wiring lines 25B are positioned between the third conductive members 20C and the second gate wiring lines 24B in the second direction y.

As shown in FIGS. 3 and 10, each of the relay terminals 26 is bonded to two of the conductive members 20 that are adjacent to each other in the first direction x. Each of the relay terminals 26 has the shape of a flat plate perpendicular to the thickness direction z. Each of the relay terminals 26 is made of a metal plate. The composition of the metal plate includes copper. Each of the relay terminals 26 may have a thickness of 0.3 mm to 0.5 mm, for example. Accordingly, each of the relay terminals 26 is thinner than each of the input terminals 41 and the output terminal 42. Furthermore, each of the relay terminals 26 is thicker than each of the conductive members 20.

As shown in FIG. 10, the relay terminals 26 include a first relay terminal 26A, a second relay terminal 26B, and a third relay terminal 26C. The second relay terminal 26B and the third relay terminal 26C each have the same shape as the first relay terminal 26A. The first relay terminal 26A extends across the gap S and is bonded to the first conductive members 20A. As a result, the first conductive members 20A are electrically connected to each other. The second relay terminal 26B extends across the gap S and is bonded to the second conductive members 20B. As a result, the second conductive members 20B are electrically connected to each other. The third relay terminal 26C extends across the gap S and is bonded to the third conductive members 20C. As a result, the third conductive members 20C are electrically connected to each other. The first relay terminal 26A, the second relay terminal 26B, and the third relay terminal 26C are arranged along the second direction y.

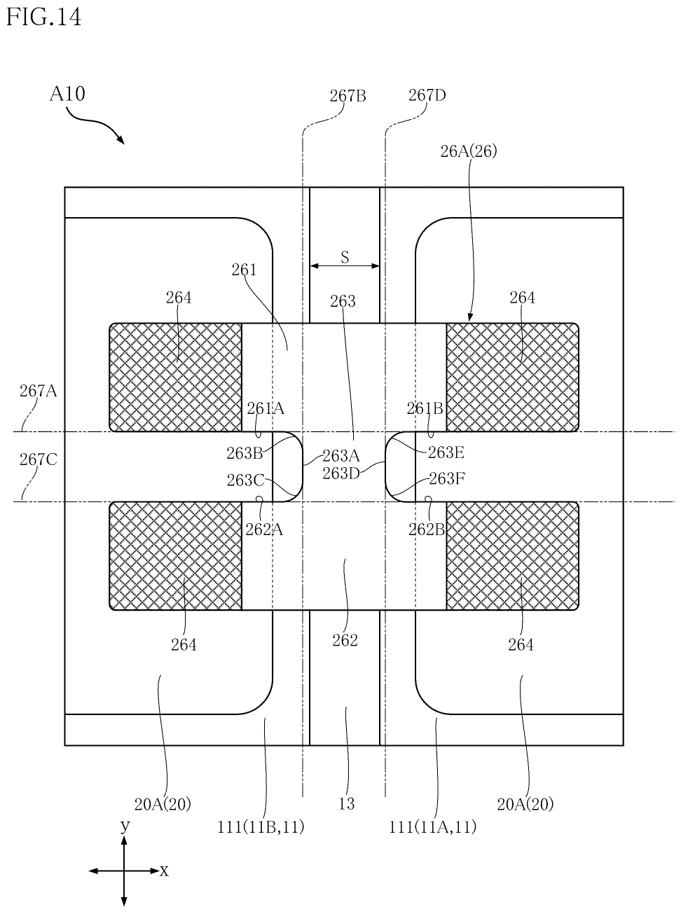

As shown in FIG. 14, each of the relay terminals 26 has a first strip portion 261, a second strip portion 262, and a connecting portion 263. Although FIG. 14 shows the first relay terminal 26A among the relay terminals 26, each of the second relay terminal 26B and the third relay terminal 26C also has the same configuration as the first relay terminal 26A. Accordingly, the specific configurations of the relay terminals 26 will be described with the first relay terminal 26A as a representative among the relay terminals 26.

As shown in FIG. 14, each of the first strip portion 261 and the second strip portion 262 is bonded to two conductive members 20 (the first conductive members 20A), which are two of the conductive members 20 and are adjacent to each other in the first direction x. The first strip portion 261 and the second strip portion 262 extend in the first direction x and are adjacent to each other in the second direction y. The connecting portion 263 connects the first strip portion 261 and the second strip portion 262 to each other. The connecting portion 263 is located between the first strip portion 261 and the second strip portion 262 in the second direction y.

As shown in FIG. 14, the first strip portion 261 has a first side 261A and a third side 261B. The first side 261A and the third side 261B extend in the first direction x. The third side 261B is located opposite from the first side 261A with the connecting portion 263 therebetween in the first direction x.

As shown in FIG. 14, the second strip portion 262 has a second side 262A and a fourth side 262B. The second side 262A and the fourth side 262B extend in the first direction x. The fourth side 262B is located opposite from the second side 262A with the connecting portion 263 therebetween in the first direction x. The second side 262A faces the first side 261A of the first strip portion 261 in the second direction y. The fourth side 262B faces the third side 261B of the first strip portion 261 in the second direction y.

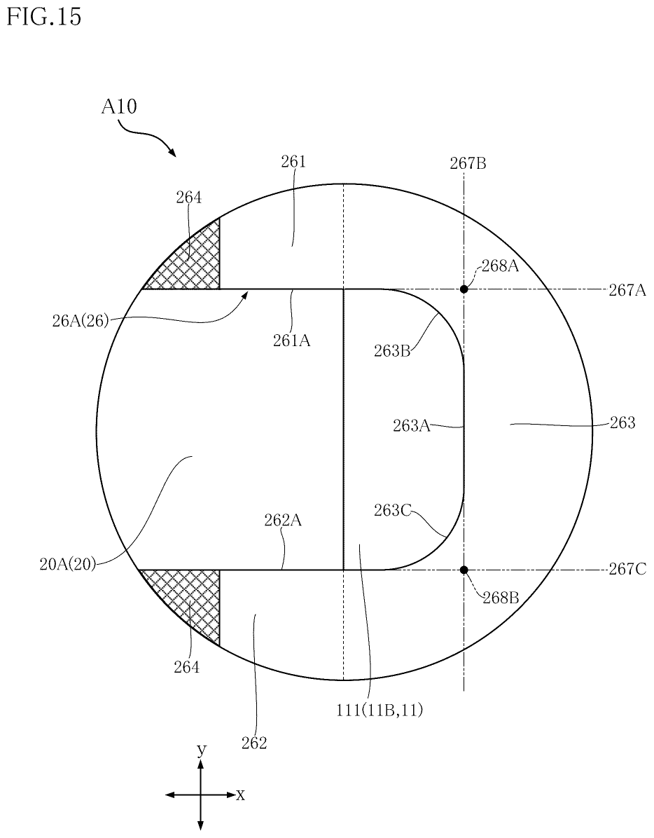

As shown in FIGS. 14 and 15, the connecting portion 263 has a first intermediate side 263A, a first connecting side 263B, and a second connecting side 263C. The first intermediate side 263A extends in the second direction y. The first connecting side 263B connects the first intermediate side 263A and the first side 261A of the first strip portion 261 to each other. The second connecting side 263C connects the first intermediate side 263A and the second side 262A of the second strip portion 262 to each other.

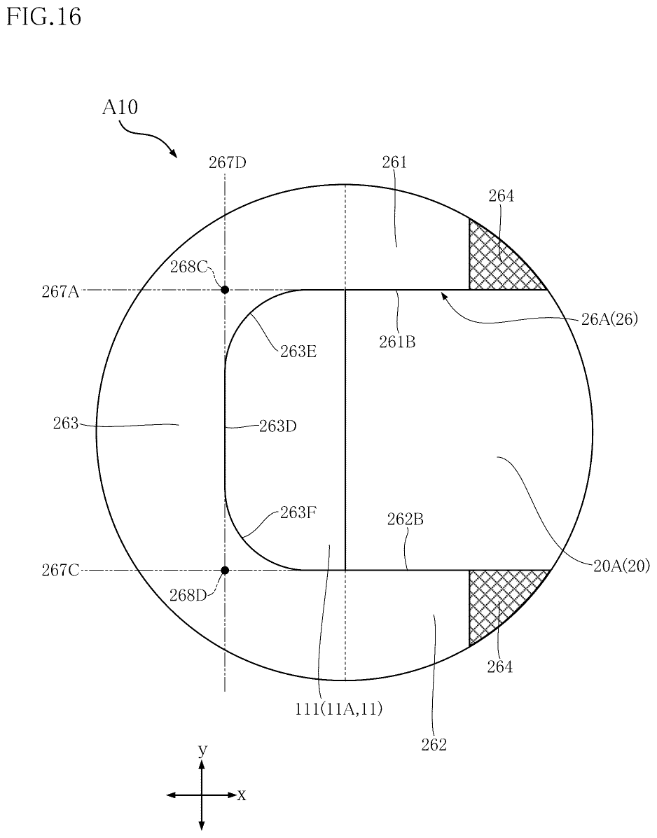

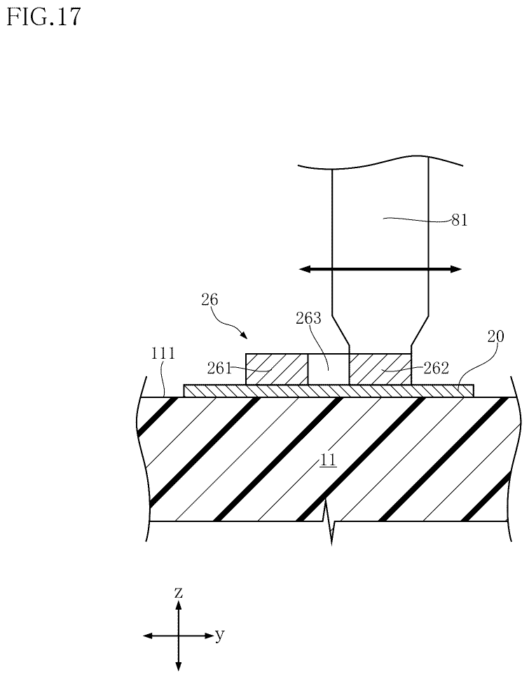

As shown in FIGS. 14 and 16, the connecting portion 263 has a second intermediate side 263D, a third connecting side 263E, and a fourth connecting side 263F. The second intermediate side 263D extends in the second direction y. The second intermediate side 263D is located opposite from the first intermediate side 263A in the first direction x. The third connecting side 263E connects the second intermediate side 263D and the third side 261B of the first strip portion 261 to each other. The fourth connecting side 263F connects the second intermediate side 263D and the fourth side 262B of the second strip portion 262 to each other.

As shown in FIG. 14, a first virtual line 267A, a second virtual line 267B, a third virtual line 267C, and a fourth virtual line 267D are set for the relay terminal 26. The first virtual line 267A extends in the first direction x, and overlaps with the first side 261A and the third side 261B of the first strip portion 261 as viewed in the thickness direction z. The second virtual line 267B extends in the second direction y, and overlaps with the first intermediate side 263A of the connecting portion 263 as viewed in the thickness direction z. The third virtual line 267C extends in the first direction x, and overlaps with the second side 262A and the fourth side 262B of the second strip portion 262 as viewed in the thickness direction z. The fourth virtual line 267D extends in the second direction y, and overlaps with the second intermediate side 263D of the connecting portion 263 as viewed in the thickness direction z.

In this case, as shown in FIG. 15, the first connecting side 263B of the connecting portion 263 is located away from a first virtual intersection 268A as viewed in the thickness direction z. The first virtual intersection 268A is the intersection of the first virtual line 267A and the second virtual line 267B. As viewed in the thickness direction z, the second connecting side 263C of the connecting portion 263 is located away from a second virtual intersection 268B. The second virtual intersection 268B is the intersection of the second virtual line 267B and the third virtual line 267C.

Furthermore, as shown in FIG. 16, the third connecting side 263E of the connecting portion 263 is located away from a third virtual intersection 268C as viewed in the thickness direction z. The third virtual intersection 268C is the intersection of the first virtual line 267A and the fourth virtual line 267D. As viewed in the thickness direction z, the fourth connecting side 263F of the connecting portion 263 is located away from a fourth virtual intersection 268D. The fourth virtual intersection 268D is the intersection of the third virtual line 267C and the fourth virtual line 267D.

As shown in FIGS. 15 and 16, the first connecting side 263B, the second connecting side 263C, the third connecting side 263E, and the fourth connecting side 263F of the connecting portion 263 in the semiconductor device A10 each form a curve that is recessed toward the inside of the first relay terminal 26A as viewed in the thickness direction z. As viewed in the thickness direction z, a part of the connecting portion 263 is surrounded by the first connecting side 263B, the first virtual line 267A, and the second virtual line 267B.

The first strip portion 261 and the second strip portion 262 of each relay terminal 26 are bonded, by the ultrasonic vibrations shown in FIG. 17, to two of the conductive members that are adjacent to each other in the first direction x.

As shown in FIG. 17, one side of each of the first strip portion 261 and the second strip portion 262 in the first direction x is in contact with one of the two conductive members 20 adjacent to each other in the first direction x. In this state, a capillary 81 is used to apply a compression load in the thickness direction z to an end of each of the first strip portion 261 and the second strip portion 262 that overlaps with the conductive member 20 in the thickness direction z. Next, ultrasonic vibrations along the second direction y are generated in the capillary 81. The frequency of the ultrasonic vibrations may be at least 20 kHz and at most 60 kHz, for example. As a result, the end of each of the first strip portion 261 and the second strip portion 262 is bonded to the conductive member 20. Note that the ultrasonic vibrations along the second direction y as shown in FIG. 17 may be applied to a plurality of teeth provided for an inner connecting portion 412 of each of the input terminals 41 and to a plurality of teeth provided for an inner connecting portion 422 of the output terminal 42, whereby the teeth of each of these terminals are bonded to a target object.

As shown in FIG. 10, the semiconductor device A10 includes a plurality of first conductive members 27A. The first conductive members 27A extend across the gap S and are bonded to the gate wiring lines 24. This allows the first gate wiring lines 24A to be electrically connected to each other, and also allows the second gate wiring lines 24B to be electrically connected to each other. In the semiconductor device A10, each of the first conductive members 27A is constituted by a plurality of wires. The wires may be made of aluminum (Al), for example. The first conductive members 27A are along the first direction x.

As shown in FIG. 10, the semiconductor device A10 includes a plurality of second conductive members 27B. The second conductive members 27B extend across the gap S and are bonded to the detection wiring lines 25. This allows the first detection wiring lines 25A to be electrically connected to each other, and also allows the second detection wiring lines 25B to be electrically connected to each other. In the semiconductor device A10, each of the second conductive members 27B is constituted by a plurality of metal wires. The wires may be made of aluminum, for example. The second conductive members 27B are along the first direction x.

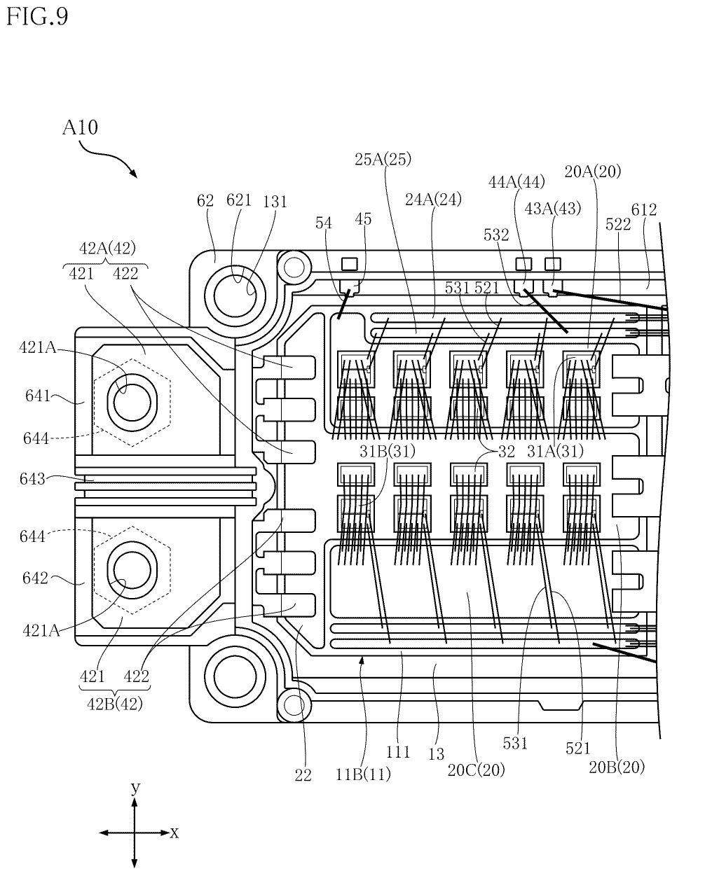

As shown in FIG. 8, the semiconductor device A10 includes a pair of pads 28. The pair of pads 28 are adjacent to each other in the first direction x. The pair of pads 28 are located at a corner of the first base member 11A. The pair of pads 28 are arranged in proximity to one of the first conductive members 20A that is bonded to the first base member 11A.

As shown in FIGS. 2 and 3, the input terminals 41 are some of the outer connecting terminals provided for the semiconductor device A10. The input terminals 41 are bonded to a DC power source located outside the semiconductor device A10. The input terminals 41 are supported by the case 60. Each of the input terminals 41 is made of a metal plate. The metal plate contains copper, for example. Each of the input terminals 41 has a thickness of 1.0 mm.

The input terminals 41 include a first input terminal 41A and a second input terminal 41B. The first input terminal 41A is a positive electrode (P terminal). The first input terminal 41A is bonded to a first pad portion 21 of a first conductive member 20A, which is one of the first conductive members 20A and is arranged on the first base member 11A. As a result, the first input terminal 41A is electrically connected to the first conductive members 20A. The second input terminal 41B is a negative electrode (N terminal). The second input terminal 41B is bonded to a third pad portion 23 of a third conductive member 20C, which is one of the third conductive members 20C and is arranged on the first base member 11A. As a result, the second input terminal 41B is electrically connected to the third conductive members 20C. The first input terminal 41A and the second input terminal 41B are adjacent to each other in the second direction y.

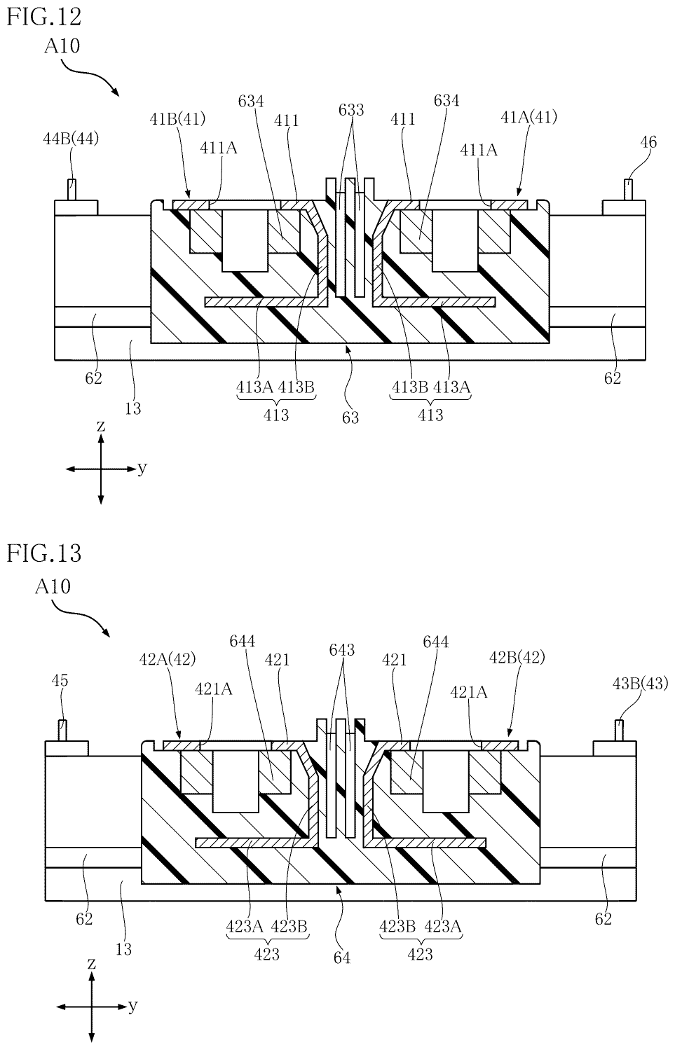

As shown in FIGS. 8 and 12, each of the first input terminal 41A and the second input terminal 41B has an outer connecting portion 411, an inner connecting portion 412, and an intermediate portion 413.

The outer connecting portion 411 is exposed from the semiconductor device A10 and has the shape of a flat plate perpendicular to the thickness direction z. A cable of the

DC power source, for example, is bonded to the outer connecting portion 411. The outer connecting portion 411 is supported by the case 60. The outer connecting portion 411 is provided with a connecting hole 411A that penetrates through the outer connecting portion 411 in the thickness direction z. A fastener such as a bolt is inserted in the connecting hole 411A. Note that the surface of the outer connecting portion 411 may be plated with nickel (Ni).

The inner connecting portion 412 of the first input terminal 41A has a comb-like shape, and is bonded to the first pad portion 21 of one of the first conductive members 20A. The inner connecting portion 412 of the second input terminal 41B also has a comb-like shape, and is bonded to the third pad portion 23 of one of the third conductive members 20C. In the semiconductor device A10, each of the inner connecting portions 412 has three teeth arranged in the second direction y. These teeth are bent in the thickness direction z. Accordingly, each of the teeth has a hook shape as viewed in the second direction y. The teeth are bonded to the first pad portion 21 and the third pad portion 23 by ultrasonic vibrations.

Each of the intermediate portions 413 connects an outer connecting portion 411 and an inner connecting portion 412. The cross-section of the intermediate portion 413 relative to the first direction x has an L shape. The intermediate portion 413 has a base 413A and an upright portion 413B. The base 413A is provided along the first direction x and the second direction y. One end of the base 413A in the first direction x is connected to the inner connecting portion 412. The upright portion 413B stands on the base 413A in the thickness direction z. One end of the upright portion 413B in the thickness direction z is connected to the outer connecting portion 411.

As shown in FIGS. 2 and 3, the output terminal 42 is one of the outer connecting terminals provided for the semiconductor device A10. The output terminal 42 is bonded to a power-supply target (e.g., a motor) located outside the semiconductor device A10. The output terminal 42 is supported by the case 60, and is located opposite from the input terminals 41 with respect to the base members 11 in the first direction x. The output terminal 42 is made of a metal plate. The metal plate contains copper, for example. The output terminal 42 has a thickness of 1.0 mm.

In the semiconductor device A10, the output terminal 42 is divided into two terminal portions, namely a first terminal portion 42A and a second terminal portion 42B. Alternatively, the output terminal 42 may be a single terminal with the first terminal portion 42A integrated with the second terminal portion 42B. The first terminal portion 42A and the second terminal portion 42B are bonded to a second pad portion 22 of a second conductive member 20B, which is one of the second conductive members 20B and is arranged on the second base member 11B. As a result, the output terminal 42 is electrically connected to the second conductive members 20B. The first terminal portion 42A and the second terminal portion 42B are adjacent to each other in the second direction y.

As shown in FIGS. 9 and 13, each of the first terminal portion 42A and the second terminal portion 42B has an outer connecting portion 421, an inner connecting portion 422, and an intermediate portion 423.

The outer connecting portion 421 is exposed from the semiconductor device A10 and has the shape of a flat plate perpendicular to the thickness direction z. A cable electrically connected to a power-supply target, for example, is bonded to the outer connecting portion 421. The outer connecting portion 421 is supported by the case 60. The outer connecting portion 421 is provided with a connecting hole 421A that penetrates through the outer connecting portion 421 in the thickness direction z. A fastener such as a bolt is inserted in the connecting hole 421A. Note that the surface of the outer connecting portion 421 may be plated with nickel.

The inner connecting portion 422 has a comb-like shape, and is bonded to the second pad portion 22 of one of the second conductive members 20B. In the semiconductor device A10, the inner connecting portion 422 has three teeth arranged in the second direction y. These teeth are bent in the thickness direction z. Accordingly, each of the teeth has a hook shape as viewed in the second direction y. The teeth are bonded to the second pad portion 22 by ultrasonic vibrations.

The intermediate portion 423 connects the outer connecting portion 421 and the inner connecting portion 422. The cross-section of the intermediate portion 423 relative to the first direction x has an L shape. The intermediate portion 423 has a base 423A and an upright portion 423B. The base 423A is provided along the first direction x and the second direction y. One end of the base 423A in the first direction x is connected to the inner connecting portion 422. The upright portion 423B stands on the base 423A in the thickness direction z. One end of the upright portion 423B in the thickness direction z is connected to the outer connecting portion 421.

As shown in FIGS. 2 to 4, the gate terminals 43 are some of the outer connecting terminals provided for the semiconductor device A10. The gate terminals 43 are electrically connected to the gate wiring lines 24. The gate terminals 43 are bonded to an external drive circuit (e.g., gate driver) for the semiconductor device A10. The gate terminals 43 are supported by the case 60. The gate terminals 43 are made of metal rods. The metal rods contain copper, for example. Note that the surfaces of the gate terminals 43 may be plated with tin (Sn) or a combination of nickel and tin. As shown in FIG. 11, the cross-section of each of the gate terminals 43 relative to the first direction x has an L shape. A part of each of the gate terminals 43 protrudes from the case 60 in a first sense of the thickness direction z in which the obverse surfaces 111 of the base members 11 face.

The gate terminals 43 include a first gate terminal 43A and a second gate terminal 43B. As shown in FIG. 10, the first gate terminal 43A is arranged in proximity to the first gate wiring lines 24A in the second direction y. As shown in FIG. 10, the second gate terminal 43B is located opposite from the first gate terminal 43A with respect to the base members 11 in the second direction y. The second gate terminal 43B is arranged in proximity to the second gate wiring lines 24B.

As shown in FIGS. 2 to 4, the detection terminals 44 are some of the outer connecting terminals provided for the semiconductor device A10. The detection terminals 44 are electrically connected to the detection wiring lines 25. The detection terminals 44 are bonded to an external control circuit for the semiconductor device A10. The detection terminals 44 are supported by the case 60. The detection terminals 44 are made of metal rods. The metal rods contain copper, for example. Note that the surfaces of the detection terminals 44 may be plated with tin or a combination of nickel and tin. As shown in FIG. 11, the cross-section of each of the detection terminals 44 relative to the first direction x has an L shape. A part of each of the detection terminals 44 protrudes from the case 60 in the first sense of the thickness direction z in which the obverse surfaces 111 of the base members 11 face.

The detection terminals 44 include a first detection terminal 44A and a second detection terminal 44B. As shown in FIG. 10, the first detection terminal 44A is adjacent to the first gate terminal 43A in the first direction x. As shown in FIG. 10, the second detection terminal 44B is adjacent to the second gate terminal 43B in the first direction x.

As shown in FIGS. 2 to 4 and FIG. 9, the semiconductor device A10 includes an input current detection terminal 45. The input current detection terminal 45 is one of the outer connecting terminals provided for the semiconductor device A10. The input current detection terminal 45 is connected to the external control circuit for the semiconductor device A10. The input current detection terminal 45 is supported by the case 60. The input current detection terminal 45 is made of a metal rod. The metal rod contains copper, for example. Note that the surface of the input current detection terminal 45 may be plated with tin or a combination of nickel and tin. The input current detection terminal 45 has the same shape as each of the gate terminals 43 shown in FIG. 11. As with the gate terminals 43 shown in FIG. 11, a part of the input current detection terminal 45 protrudes from the case 60 in the first sense of the thickness direction z in which the obverse surfaces 111 of the base members 11 face. The input current detection terminal 45 is located at the same position as the first gate terminal 43A in the second direction y. The input current detection terminal 45 is offset from the first gate terminal 43A toward the output terminal 42 in the first direction x.

As shown in FIG. 9, the semiconductor device A10 includes an input current detection wire 54. The input current detection wire 54 is bonded to the input current detection terminal 45 and one of the first conductive members 20A. In the semiconductor device A10, one end of the input current detection wire 54 is bonded to one of the first conductive members 20A that is arranged on the second base member 11B. As a result, the input current detection terminal 45 is electrically connected to the first conductive members 20A. The input current detection wire 54 may be made of aluminum, for example.

As shown in FIGS. 2 to 4 and FIG. 8, the semiconductor device A10 includes a pair of thermistor terminals 46. The pair of thermistor terminals 46 are some of the outer connecting terminals provided for the semiconductor device A10. The pair of thermistor terminals 46 are connected to the external control circuit for the semiconductor device A10. The pair of thermistor terminals 46 are supported by the case 60. The pair of thermistor terminals 46 are made of metal rods. The metal rods contain copper, for example. Note that the surfaces of the pair of thermistor terminals 46 may be plated with tin or a combination of nickel and tin. Each of the pair of thermistor terminals 46 has the same shape as each of the gate terminals 43 shown in FIG. 11. As with the gate terminals 43 shown in FIG. 11, a part of each of the pair of thermistor terminals 46 protrudes from the case 60 in the first sense of the thickness direction z in which the obverse surfaces 111 of the base members 11 face. The pair of thermistor terminals 46 are located at the same position as the first gate terminal 43A in the second direction y. The pair of thermistor terminals 46 are offset from the first gate terminal 43A toward the input terminals 41 in the first direction x. The pair of thermistor terminals 46 are adjacent to each other in the first direction x.

As shown in FIG. 8, the semiconductor device A10 includes a pair of thermistor wires 55. The pair of thermistor wires 55 are bonded to the pair of thermistor terminals 46 and the pair of pads 28, respectively. As a result, the pair of input current detection terminals 45 are electrically connected to the pair of pads 28. The pair of thermistor wires 55 may be made of aluminum, for example.

As shown in FIG. 3, the semiconductor elements 31 are bonded to the first conductive members 20A and the second conductive members 20B. The semiconductor elements 31 include a plurality of first semiconductor elements 31A and a plurality of second semiconductor elements 31B. The first semiconductor elements 31A are bonded to the first conductive members 20A and arranged in the first direction x. The second semiconductor elements 31B are bonded to the second conductive members 20B and arranged in the first direction x. Each of the semiconductor elements 31 is an insulated gate bipolar transistor (IGBT) that mainly contains silicon (Si) or silicon carbide (SiC). Each of the semiconductor elements 31 may be a metal-oxide-semiconductor field-effect transistor (MOSFET). The description of the semiconductor device A10 is provided with the assumption that the semiconductor elements 31 are IGBTs.

As shown in FIGS. 11, 18, and 19, each of the semiconductor elements 31 has a first electrode 311, a second electrode 312, and a gate electrode 313.

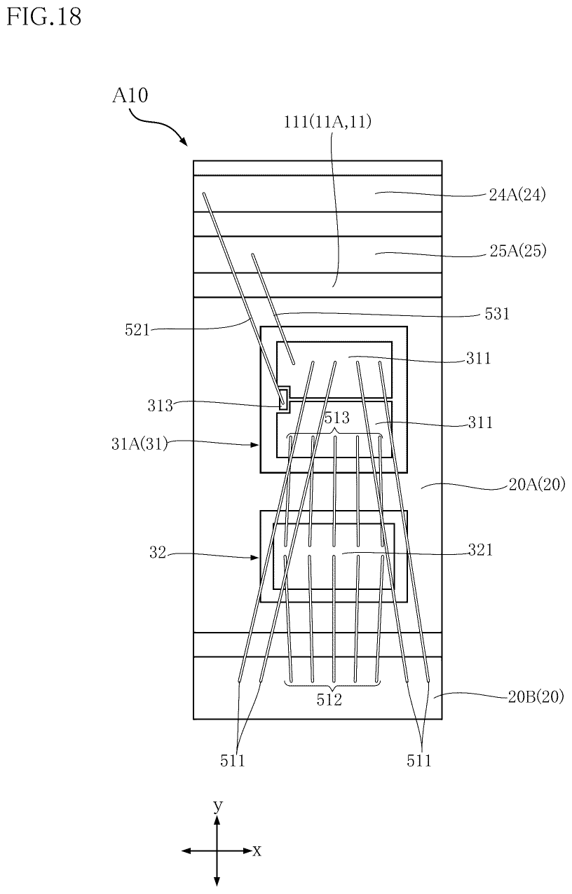

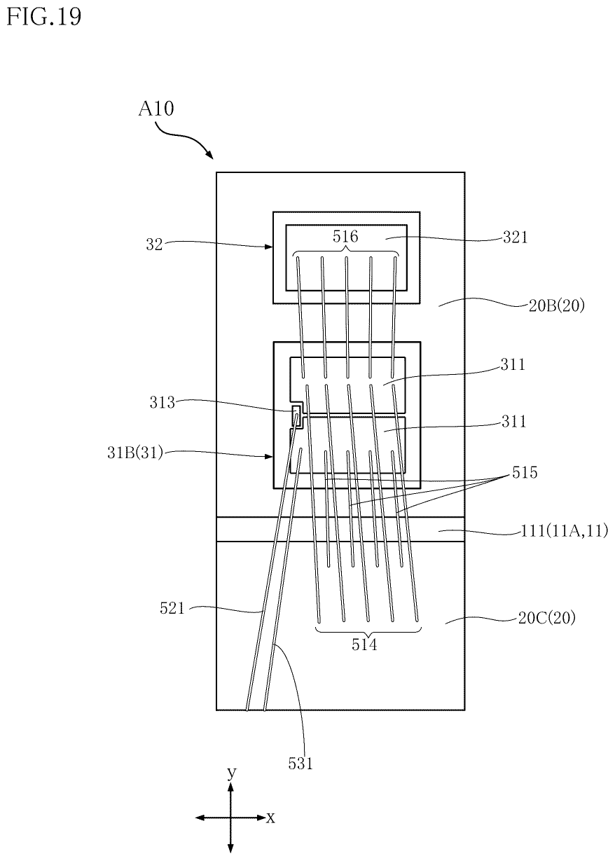

As shown in FIGS. 18 and 19, the first electrode 311 is provided on the upper end of the semiconductor element 31 located in the first sense of the thickness direction z in which the obverse surfaces 111 of the base members 11 face. Emitter current flows from inside the semiconductor element 31 to the first electrode 311. In the semiconductor device A10, the first electrode 311 includes a pair of areas adjacent to each other in the second direction y.

As shown in FIG. 11, the second electrode 312 is provided on the lower end of the semiconductor element 31 located in a second sense of the thickness direction z opposite from the first sense of the thickness direction z in which the obverse surfaces 111 of the base members 11 face. Collector current flows from the second electrode 312 to the inside of the semiconductor element 31.

Each of the second electrodes 312 is bonded to one of the first conductive members 20A and the second conductive members 20B via a conductive bonding layer 39. As a result, the second electrodes 312 of the first semiconductor elements 31A are electrically connected to the first conductive members 20A. The second electrodes 312 of the second semiconductor elements 31B are electrically connected to the second conductive members 20B. The conductive bonding layer 39 is lead-free solder that mainly contains tin, for example.

As shown in FIGS. 18 and 19, the gate electrode 313 is provided on the upper end of the semiconductor element 31 located in the first sense of the thickness direction z in which the obverse surfaces 111 of the base members 11 face. In the semiconductor device A10, the gate electrode 313 is sandwiched between the pair of areas of the first electrode 311. Gate voltage for driving the semiconductor element 31 is applied to the gate electrode 313. As viewed in the thickness direction z, the area of the gate electrode 313 is smaller than the area of the first electrode 311.

As shown in FIG. 3, the diodes 32 are bonded to the first conductive members 20A and the second conductive members 20B. The number of diodes 32 corresponds to the number of semiconductor elements 31. The diodes 32 are electrically connected to the respective semiconductor elements 31. In the semiconductor device A10, the diodes 32 are Schottky barrier diodes.

As shown in FIGS. 11, 18, and 19, each of the diodes 32 has an anode electrode 321 and a cathode electrode 322. The anode electrode 321 is provided on the upper end of the diode 32 located in the first sense of the thickness direction z in which the obverse surfaces 111 of the base members 11 face. The cathode electrode 322 is provided on the lower end of the diode 32 located in the second sense of the thickness direction z opposite from the first sense of the thickness direction z in which the obverse surfaces 111 of the base members 11 face. The cathode electrode 322 is bonded to one of the first conductive members 20A and the second conductive members 20B via the conductive bonding layer 39. As a result, the cathode electrode 322 of each diode 32 is electrically connected to one of the first conductive members 20A and the second conductive members 20B.

As shown in FIGS. 3 and 8, the semiconductor device A10 includes a thermistor 33. The thermistor 33 is electrically bonded to the pair of pads 28. In the semiconductor device A10, the thermistor 33 is a negative temperature coefficient (NTC) thermistor. The NTC thermistor has a characteristic that the resistance is lowered gradually as the temperature rises. The thermistor 33 is used as a temperature detection sensor for the semiconductor device A10. The thermistor 33 is electrically connected to the pair of thermistor terminals 46 via the pair of pads 28 and the pair of thermistor wires 55.

As shown in FIGS. 18 and 19, the semiconductor device A10 includes a plurality of first wires 511 to a plurality of sixth wires 516, a plurality of first gate wires 521, and a plurality of first detection wires 531. These wires are individually bonded to the semiconductor elements 31 and the diodes 32. The composition of these wires includes aluminum, for example.

The descriptions of the first wires 511, the second wires 512, and the third wires 513, which are individually bonded to the first semiconductor elements 31A and the diodes 32 bonded to the first conductive members 20A, will be provided with reference to FIG. 18. The first wires 511 are bonded to the first electrodes 311 of the first semiconductor elements 31A and the second conductive members 20B. The second wires 512 are bonded to the anode electrodes 321 of the diodes 32 and the second conductive members 20B. As a result, the first electrodes 311 of the first semiconductor elements 31A and the anode electrodes 321 of the diodes 32 corresponding the first electrodes 311 are electrically connected to the second conductive members 20B. The third wires 513 are bonded to the first electrodes 311 of the first semiconductor elements 31A and the anode electrodes 321 of the diodes 32 corresponding to the first electrodes 311. As a result, the anode electrodes 321 of the diodes 32 bonded to the first conductive members 20A are electrically connected to the first electrodes 311 of the respective first semiconductor elements 31A.

The descriptions of the first gate wires 521 and first detection wires 531, which are individually bonded to the first semiconductor elements 31A, will be provided with reference to FIG. 18. The first gate wires 521 are individually bonded to the gate electrodes 313 of the first semiconductor elements 31A and the first gate wiring lines 24A. The first detection wires 531 are bonded to the first electrodes 311 of the first semiconductor elements 31A and the first detection wiring lines 25A.

The descriptions of the fourth wires 514, the fifth wires 515, and the sixth wires 516, which are individually bonded to the second semiconductor elements 31B and the diodes 32 bonded to the second conductive members 20B, will be provided with reference to FIG. 19. The fourth wires 514 are individually bonded to first areas of the first electrodes 311 of the second semiconductor elements 31B and the third conductive members 20C. The fifth wires 515 are bonded to second areas of the first electrodes 311 of the second semiconductor elements 31B and the third conductive members 20C. As a result, the first electrodes 311 of the second semiconductor elements 31B are electrically connected to the third conductive members 20C. The sixth wires 516 are bonded to the second areas of the first electrodes 311 of the second semiconductor elements 31B and the anode electrodes 321 of the diodes 32. As a result, the anode electrodes 321 of the diodes 32 bonded to the second conductive members 20B are electrically connected to the first electrodes 311 of the respective second semiconductor elements 31B, and electrically connected to the third conductive members 20C via the fifth wires 515.

As shown in FIG. 19, the first electrodes 311 of the second semiconductor elements 31B are electrically connected to the third conductive members 20C via the fourth wires 514 and the fifth wires 515. Accordingly, the second input terminal 41B is electrically connected to the first electrodes 311 of the second semiconductor elements 31B.

The following describes the first gate wires 521 and the first detection wires 531 individually bonded to the second semiconductor elements 31B, with reference to FIGS. 8 and 19. The first gate wires 521 are individually bonded to the gate electrodes 313 of the second semiconductor elements 31B and the second gate wiring lines 24B. The first detection wires 531 are individually bonded to the first electrodes 311 of the second semiconductor elements 31B and the second detection wiring lines 25B.

As shown in FIG. 10, the semiconductor device A10 includes a pair of second gate wires 522. The pair of second gate wires 522 are bonded to the gate terminals 43 and the gate wiring lines 24. The second gate wires 522 are made of aluminum, for example.

As shown in FIG. 10, one of the second gate wires 522 is bonded to the first gate terminal 43A and one of the first gate wiring lines 24A that is arranged on the first base member 11A. As a result, the first gate terminal 43A is electrically connected to the gate electrodes 313 of the first semiconductor elements 31A. As shown in FIG. 10, the other second gate wire 522 is bonded to the second gate terminal 43B and one of the second gate wiring lines 24B that is arranged on the second base member 11B. As a result, the second gate terminal 43B is electrically connected to the gate electrodes 313 of the second semiconductor elements 31B.

As shown in FIG. 10, the semiconductor device A10 includes a pair of second detection wires 532. The pair of second detection wires 532 are bonded to the detection terminals 44 and the detection wiring lines 25. The second detection wires 532 are made of aluminum, for example.

As shown in FIG. 10, one of the second detection wires 532 is bonded to the first detection terminal 44A and one of the first detection wiring lines 25A that is arranged on the second base member 11B. As a result, the first detection terminal 44A is electrically connected to the first electrodes 311 of the first semiconductor elements 31A. As shown in FIG. 10, the other second detection wire 532 is bonded to the second detection terminal 44B and one of the second detection wiring lines 25B that is arranged on the first base member 11A. As a result, the second detection terminal 44B is electrically connected to the first electrodes 311 of the second semiconductor elements 31B.

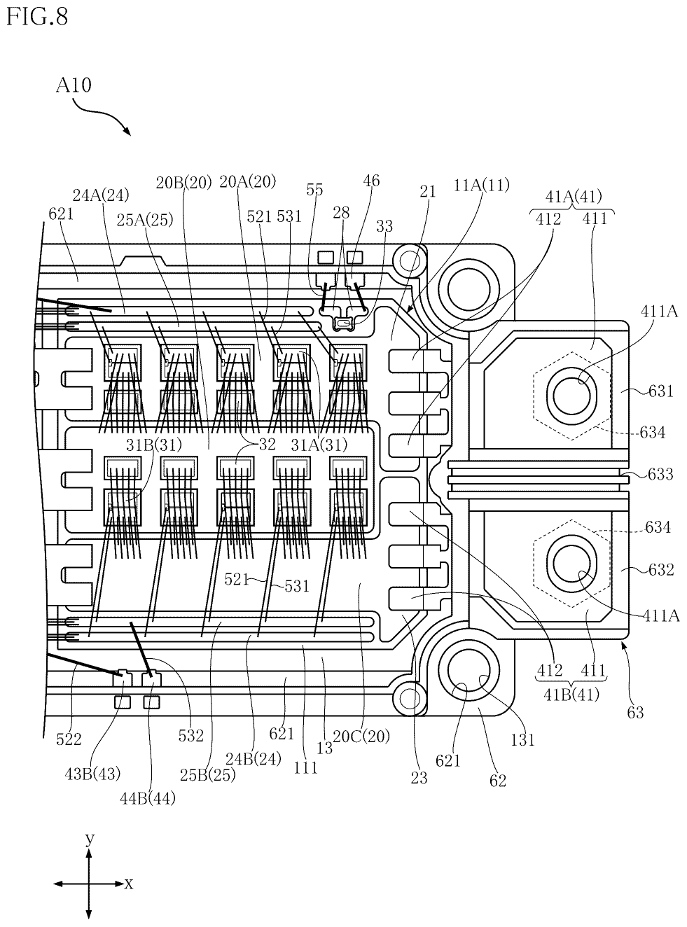

As shown in FIG. 11, the heat dissipator 13 is bonded to the reverse surface 112 of the first base member 11A and the reverse surface 112 of the second base member 11B. As such, the first base member 11A and the second base member 11B are supported by the heat dissipator 13. The heat dissipator 13 is made of a flat metal plate. The metal is copper, for example. Note that the surfaces of the heat dissipator 13 may be plated with nickel. It is possible to attach a cooling member different from the heat dissipator 13 to a portion of the heat dissipator 13 that is exposed from the semiconductor device A10. As shown in FIGS. 7 to 9, a plurality of supporting holes 131 are provided for four corners of the heat dissipator 13 as viewed in the thickness direction z. The supporting holes 131 penetrate through the heat dissipator 13 in the thickness direction z. The supporting holes 131 are used to support the heat dissipator 13, which supports the first base member 11A and the second base member 11B, at the case 60.

As shown in FIG. 11, a heat transfer member 12 is arranged on the reverse surface 112 of the first base member 11A and the reverse surface 112 of the second base member 11B. The heat transfer member 12 is made of a metal material such as copper foil. The heat transfer member 12 transfers heat generated from the semiconductor elements 31 to the heat dissipator 13.

As shown in FIG. 11, an adhesive layer 19 is provided between the heat dissipator 13 and the heat transfer member 12. The adhesive layer 19 is used to bond the heat dissipator 13 to both the first base member 11A and the second base member 11B. The adhesive layer 19 is lead-free solder that mainly contains tin, for example. The heat dissipator 13 is bonded to the first base member 11A and the second base member 11B via the heat transfer member 12 and the adhesive layer 19.

As shown in FIGS. 2 to 6, the case 60 is an electrically insulating member surrounding the first base member 11A and the second base member 11B as viewed in the thickness direction z. The case 60 is made of a material containing a synthetic resin that is highly heat-resistant, such as polyphenylene sulfide (PPS). The case 60 has a pair of first side walls 611, a pair of second side walls 612, a plurality of mounts 62, an input terminal block 63, and an output terminal block 64.

As shown in FIGS. 2 and 3, the pair of first side walls 611 are spaced apart from each other in the first direction x. Each of the pair of first side walls 611 is arranged along the second direction y and the thickness direction z, and has an end in contact with the heat dissipator 13 in the thickness direction z.

As shown in FIGS. 2 and 3, the pair of second side walls 612 are spaced apart from each other in the second direction y. Each of the pair of second side walls 612 is arranged along the first direction x and the thickness direction z, and has an end in contact with the heat dissipator 13 in the thickness direction z. Both ends of each of the second side walls 612 in the first direction x are connected to the pair of first side walls 611. The first gate terminal 43A, the first detection terminal 44A, the input current detection terminal 45, and the pair of thermistor terminals 46 are arranged inside one of the pair of second side walls 612. The second gate terminal 43B and the second detection terminal 44B are arranged inside the other second side wall 612. As shown in FIGS. 8 to 10, the ends of these terminals arranged in proximity to the first base member 11A and the second base member 11B in the thickness direction z are supported by the pair of second side walls 612.

As shown in FIGS. 2, 8, and 9, the mounts 62 are provided at the four corners of the case 60 as viewed in the thickness direction z. The heat dissipator 13 is in contact with the lower surfaces of the mounts 62. Each of the mounts 62 is provided with a mount hole 621 penetrating through in the thickness direction z. The positions of the mount holes 621 correspond to the positions of the supporting holes 131 of the heat dissipator 13. Fasteners such as pins are fitted into the mount holes 621 and the supporting holes 131, whereby the heat dissipator 13 is supported by the case 60.

As shown in FIGS. 2, 5, and 8, the input terminal block 63 protrudes outward in the first direction x from one of the first side walls 611. The input terminal block 63 supports the input terminals 41. The input terminal block 63 includes a first terminal block 631 and a second terminal block 632. The first terminal block 631 and the second terminal block 632 are spaced apart from each other in the second direction y. The first terminal block 631 supports the first input terminal 41A. The outer connecting portion 411 of the first input terminal 41A is exposed from the first terminal block 631. The second terminal block 632 supports the second input terminal 41B. The outer connecting portion 411 of the second input terminal 41B is exposed from the second terminal block 632. A plurality of grooves 633 extending in the first direction x are formed between the first terminal block 631 and the second terminal block 632. As shown in FIGS. 8 and 12, a pair of nuts 634 are provided inside the first terminal block 631 and the second terminal block 632. The pair of nuts 634 correspond to the pair of connecting holes 411A formed in the first input terminal 41A and the second input terminal 41B. Fasteners, such as bolts, inserted in the pair of connecting holes 411A, fit in the nuts 634.

As shown in FIGS. 2, 6, and 9, the output terminal block 64 protrudes outward in the first direction x from the other first side wall 611. The output terminal block 64 supports the output terminal 42. The output terminal block 64 includes a first terminal block 641 and a second terminal block 642. The first terminal block 641 and the second terminal block 642 are spaced apart from each other in the second direction y. The first terminal block 641 supports the first terminal portion 42A of the output terminal 42. The outer connecting portion 421 of the first terminal portion 42A is exposed from the first terminal block 641. The second terminal block 642 supports the second terminal portion 42B of the output terminal 42. The outer connecting portion 421 of the second terminal portion 42B is exposed from the second terminal block 642. A plurality of grooves 643 extending in the first direction x are formed between the first terminal block 641 and the second terminal block 642. As shown in FIGS. 9 and 13, a pair of nuts 644 are provided inside the first terminal block 641 and the second terminal block 642. The pair of nuts 644 correspond to the pair of connecting holes 421A formed in the first terminal portion 42A and the second terminal portion 42B. Fasteners, such as bolts, inserted in the pair of connecting holes 421A, fit in the pair of nuts 644.

As shown in FIG. 2, an internal area of the semiconductor device A10, which is formed by the heat dissipator 13 and the case 60, is closed by a top plate 69. The top plate 69 faces the obverse surfaces 111 of the base members 11. The top plate 69 is supported by the pair of first side walls 611 and the pair of second side walls 612 of the case 60. The top plate 69 is made of a material containing a synthetic resin that is electrically insulative. It is possible to fill the internal area of the semiconductor device A10 with silicone gel or the like, instead of the top plate 69.

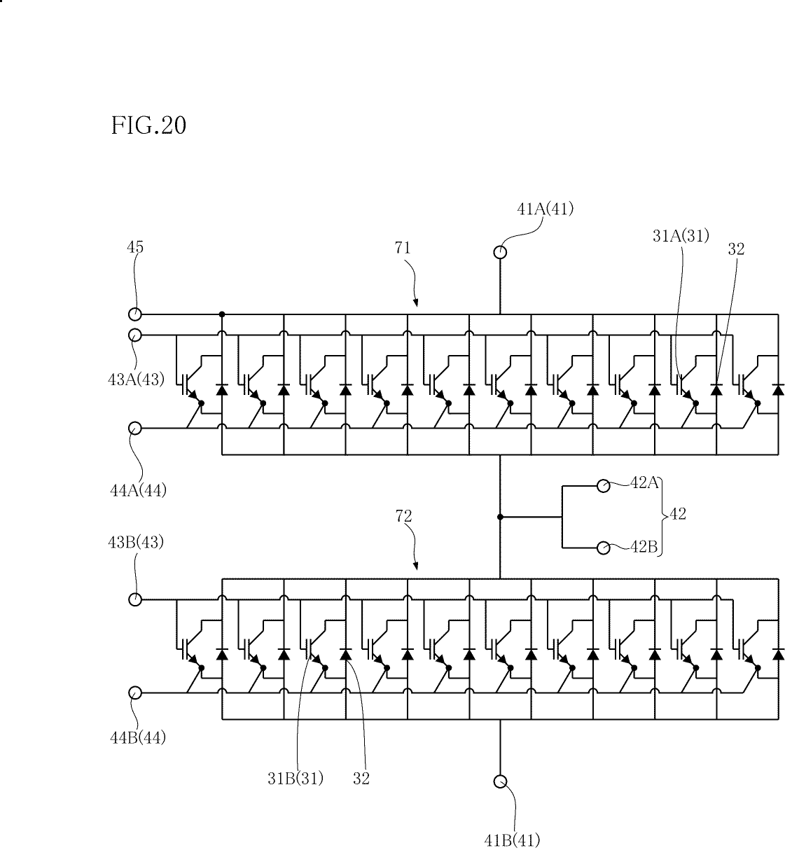

Next, the circuit configuration in the semiconductor device A10 will be described with reference to FIG. 20.

As shown in FIG. 20, two switching circuits, namely an upper arm circuit 71 and a lower arm circuit 72, are configured in the semiconductor device A10. The upper arm circuit 71 is configured with the first conductive members 20A, the first semiconductor elements 31A, and the diodes 32 bonded to the first conductive members 20A. The first semiconductor elements 31A and the diodes 32 in the upper arm circuit 71 are connected in parallel between the first input terminal 41A and the output terminal 42. The gate electrodes 313 of the first semiconductor elements 31A are connected in parallel to the first gate terminal 43A. The first semiconductor elements 31A are driven simultaneously when a gate voltage is applied to the first gate terminal 43A by a drive circuit, such as a gate driver, located outside the semiconductor device A10.

The first electrodes 311 of the first semiconductor elements 31A are connected in parallel to the first detection terminal 44A. The emitter current flowing through the first semiconductor elements 31A is inputted via the first detection terminal 44A to the external control circuit for the semiconductor device A10.

In the upper arm circuit 71, the voltage applied to the first conductive members 20A by the first input terminal 41A and the second input terminal 41B is inputted to the external control circuit for the semiconductor device A10 via the input current detection terminal 45.

The lower arm circuit 72 is configured with the second conductive members 20B, the second semiconductor elements 31B, and the diodes 32 bonded to the second conductive members 20B. The second semiconductor elements 31B and the diodes 32 in the lower arm circuit 72 are connected in parallel between the output terminal 42 and the second input terminal 41B. The gate electrodes 313 of the second semiconductor elements 31B are connected in parallel to the second gate terminal 43B. The second semiconductor elements 31B are driven simultaneously when a gate voltage is applied to the second gate terminal 43B by a drive circuit, such as a gate driver, located outside the semiconductor device A10.

The first electrodes 311 of the second semiconductor elements 31B are connected in parallel to the second detection terminal 44B. The emitter current flowing through the second semiconductor elements 31B is inputted via the second detection terminal 44B to the external control circuit for the semiconductor device A10.

DC voltage is applied to the first input terminal 41A and the second input terminal 41B, and the semiconductor elements 31 in the upper arm circuit 71 and the lower arm circuit 72 are driven, whereby AC voltages of various frequencies are output from the output terminal 42. The AC voltages are supplied to power-supply targets such as motors.

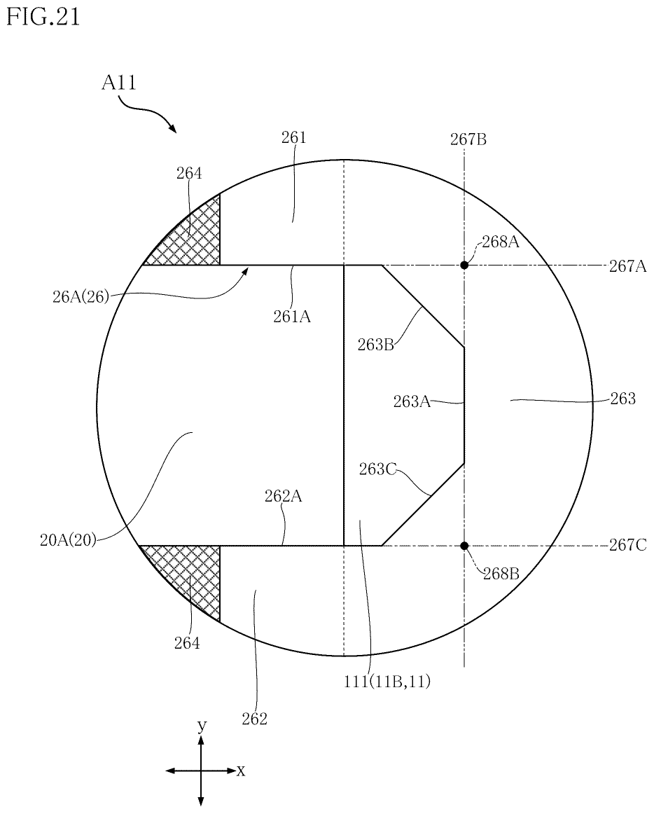

Next, a semiconductor device A11, which is a first variation of the semiconductor device A10, will be described with reference to FIG. 21.

As shown in FIG. 21, the semiconductor device A11 is different from the semiconductor device A10 in the configuration of each of the relay terminals 26. Although FIG. 21 shows the first relay terminal 26A among the relay terminals 26, each of the second relay terminal 26B and the third relay terminal 26C also has the same configuration as the first relay terminal 26A. Accordingly, the descriptions of the semiconductor device A11 will be provided with the first relay terminal 26A as a representative among the relay terminals 26.

As shown in FIG. 21, in the semiconductor device A11, the first connecting side 263B, the second connecting side 263C, the third connecting side 263E, and the fourth connecting side 263F of the connecting portion 263 of the first relay terminal 26A each form a straight line. The first connecting side 263B, the second connecting side 263C, the third connecting side 263E, and the fourth connecting side 263F are inclined relative to the first direction x and the second direction y. As viewed in the thickness direction z, a part of the connecting portion 263 is surrounded by the first connecting side 263B, the first virtual line 267A, and the second virtual line 267B.

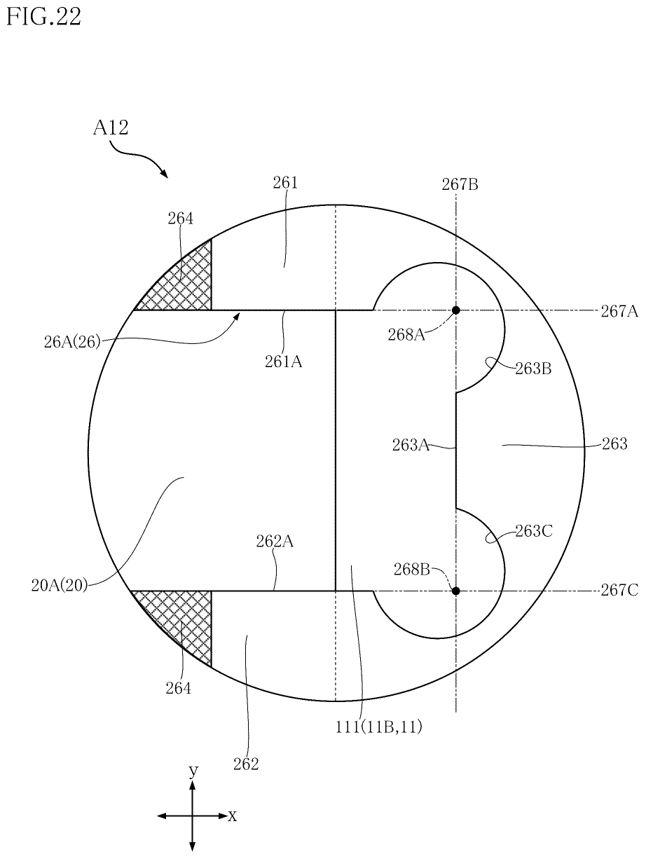

Next, a semiconductor device A12, which is a second variation of the semiconductor device A10, will be described with reference to FIG. 22.

As shown in FIG. 22, the semiconductor device A12 is different from the semiconductor device A10 in the configuration of the first relay terminal 26A. Although FIG. 22 shows the first relay terminal 26A among the relay terminals 26, each of the second relay terminal 26B and the third relay terminal 26C also has the same configuration as the first relay terminal 26A. Accordingly, the descriptions of the semiconductor device A12 will be provided with the first relay terminal 26A as a representative among the relay terminals 26.

As shown in FIG. 22, in the semiconductor device A12, the first connecting side 263B, the second connecting side 263C, the third connecting side 263E, and the fourth connecting side 263F of the connecting portion 263 of the first relay terminal 26A each form a curve that is recessed toward the inside of the first relay terminal 26A as viewed in the thickness direction z. As viewed in the thickness direction z, the first connecting side 263B extends across the first virtual line 267A the second virtual line 267B.

The following describes advantages of the semiconductor device A10.

The semiconductor device A10 includes the relay terminals 26 each bonded to two conductive members 20 adjacent to each other in the first direction x. Each of the relay terminals 26 has a first strip portion 261, a second strip portion 262, and a connecting portion 263. The first strip portion 261 has a first side 261A. The connecting portion 263 has a first intermediate side 263A, and a first connecting side 263B connecting the first side 261A and the first intermediate side 263A. As viewed in the thickness direction z, the first connecting side 263B is located away from the first virtual intersection 268A that is the intersection of the first virtual line 267A overlapping with the first side 261A and the second virtual line 267B overlapping with the first intermediate side 263A. Note that when a relay terminal 26 is bonded to two conductive members 20 by the ultrasonic vibrations shown in FIG. 17, the repeated stress resulting from the ultrasonic vibrations transferred from the capillary 81 to the relay terminal 26 concentrates at the boundary between either the first strip portion 261 or the second strip portion 262 and the connecting portion 263. In view of this, the configuration as described above is employed to alleviate the concentration of the repeated stress. This allows the semiconductor device A10 to suppress cracks in the relay terminal 26 bonded to the two conductive members 20 during the manufacturing process of the semiconductor device A10.

The concentration of the repeated stress at the boundary between either the first strip portion 261 or the second strip portion 262 and the connecting portion 263 can also be alleviated by the configuration of the relay terminals 26 of each of the semiconductor device A11 and the semiconductor device A12, as well as by the configuration of the relay terminals 26 of the semiconductor device A10.

The thickness of each of the relay terminals 26 is thicker than each of the two conductive members 20. This lowers the electric resistance value of the relay terminal 26, thus allowing the reduction of the internal resistance (parasitic resistance) caused by the relay terminal 26 in the semiconductor device A10. Furthermore, since the thermal conductivity of the relay terminal 26 is enhanced, uneven thermal distribution between the two conductive members 20 resulting from the heat generated by the semiconductor elements 31 is alleviated. This makes it possible to reduce the concentration of thermal stress at the two base members 11 on which the two conductive members 20 are arranged respectively.

The semiconductor device A10 further includes the first input terminal 41A electrically connected to two conductive members 20 (the first conductive members 20A) and the second input terminal 41B electrically connected to a semiconductor element 31 (any of the second semiconductor elements 31B). The first input terminal 41A and the second input terminal 41B are adjacent to each other. As a result, when voltage is applied to the first input terminal 41A and the second input terminal 41B, mutual inductance is generated between the first input terminal 41A and the second input terminal 41B. This makes it possible to reduce the parasitic inductance of the semiconductor device A10.

The semiconductor device A10 further includes the heat dissipator 13 located opposite from the two conductive members with the two base members 11 therebetween in the thickness direction z. The two base members 11 are supported by the heat dissipator 13. In this way, the heat transferred from the semiconductor elements 31 to the two conductive members is easily released to the outside so as to alleviate the concentration of the thermal stress in the base members 11 more efficiently.

The following describes a semiconductor device A20 according to a second embodiment of the present disclosure, with reference to FIG. 23. In this figure, elements that are the same as or similar to the elements of the semiconductor device A10 described above are provided with the same reference numerals, and descriptions thereof are omitted.

The semiconductor device A20 is different from the semiconductor device A10 in the configuration of each of the relay terminals 26. Although FIG. 23 shows the first relay terminal 26A among the relay terminals 26, each of the second relay terminal 26B and the third relay terminal 26C also has the same configuration as the first relay terminal 26A. Accordingly, the descriptions of the semiconductor device A20 will be provided with the first relay terminal 26A as a representative among the relay terminals 26.

As shown in FIG. 23, the first relay terminal 26A has a plurality of bonding marks 264, one of which includes a first region 264A and a second region 264B. The second region 264B overlaps with the first region 264A. It does not matter which of the first region 264A and the second region 264B is formed first. As viewed in the thickness direction z, the first region 264A and the second region 264B are surrounded by the periphery of one of the first conductive members 20A.

As shown in FIG. 23, the second region 264B has a protrusion 264C located outward beyond the first region 264A.

The area of the protrusion 264C is smaller than the area of the first region 264A. The protrusion 264C is located between the first region 264A and one of the bonding marks 264 that is located adjacent to the first region 264A in the first direction x.

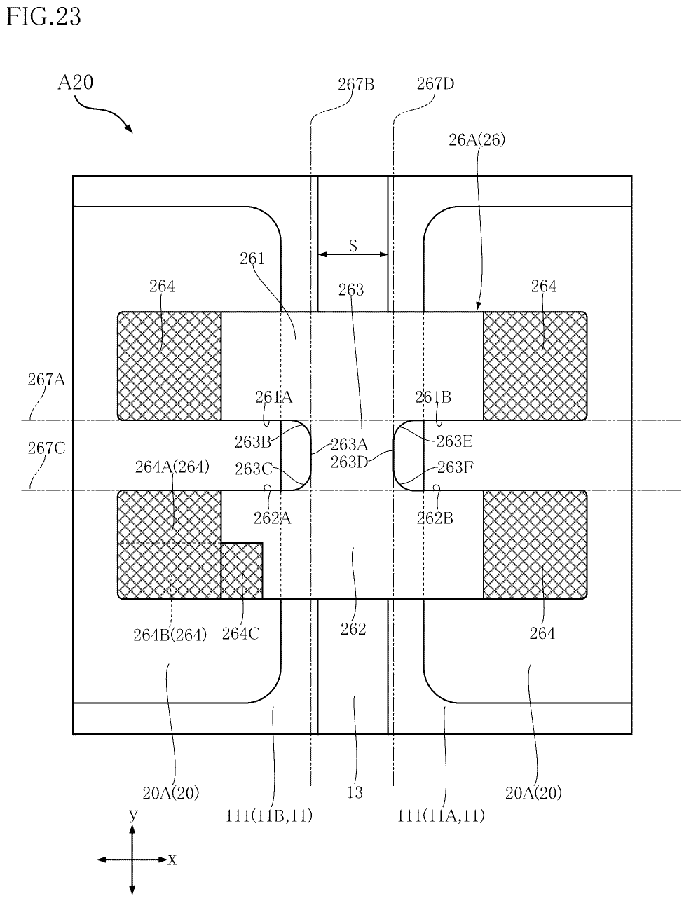

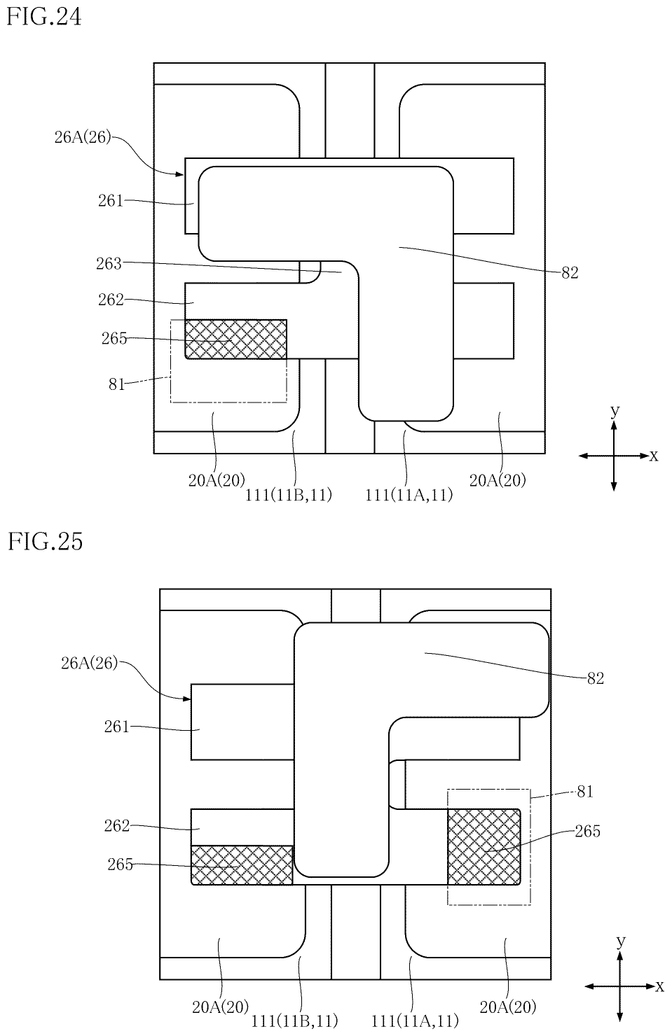

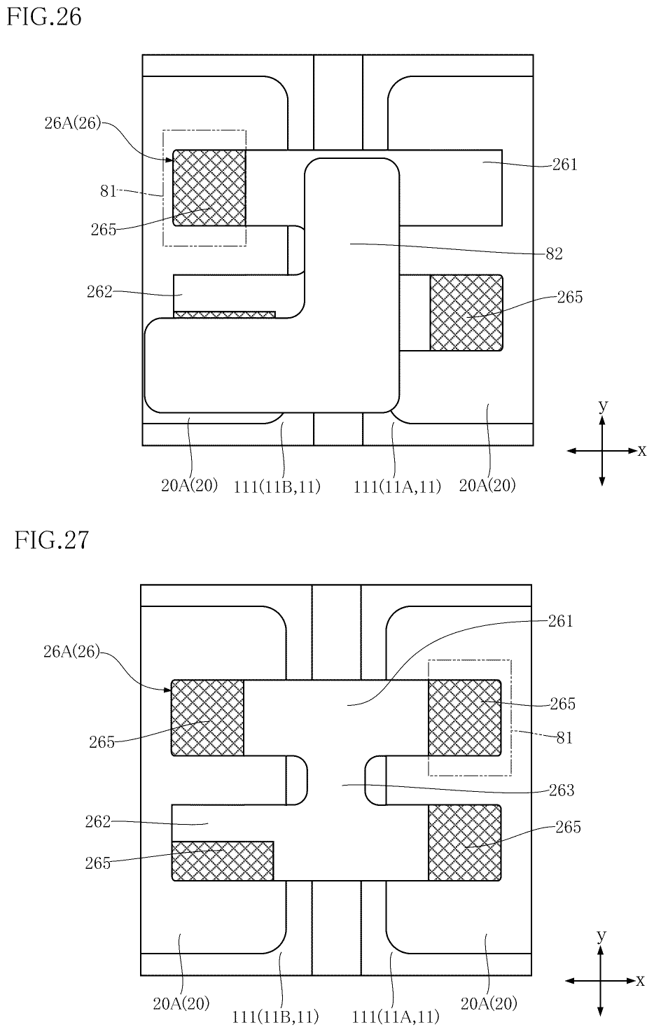

The following describes a method for manufacturing the semiconductor device A20, which includes a first step and a second step. In the first step, a relay terminal 26 (the first relay terminal 26A) is bonded to two conductive members (the first conductive members 20A) adjacent to each other in the first direction x by the ultrasonic vibrations shown in FIG. 17. In the second step, semiconductor elements 31 (the first semiconductor elements 31A) are bonded to the two conductive members 20. Although the order of the first step and the second step is not particularly limited, it is preferable to perform the first step before the second step to prevent the transmission of vibrations to the semiconductor elements 31 as a result of bonding the relay terminal 26. The following describes the first step in detail with reference to FIGS. 24 to 28. Specific descriptions of the second step will be omitted.

As shown in FIG. 24, after the relay terminal 26 is arranged on the two conductive members 20, a clamp 82 is used to press the relay terminal 26 against the two conductive members. Then, the capillary 81 is pressed against an area of either one of the first strip portion 261 and the second strip portion 262 (an area of the second strip portion 262 in FIG. 24) of the relay terminal 26 that overlaps with one of the two conductive members 20 as viewed in the thickness direction z, so that a first bonding mark 265 is formed in the area.

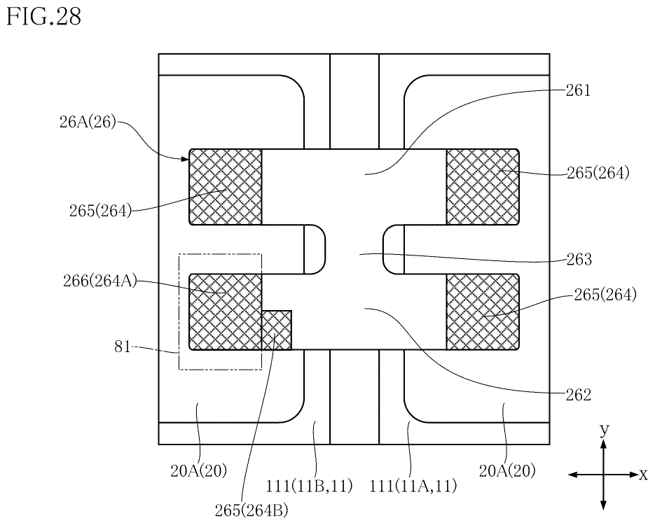

Next, as shown in FIGS. 25 to 27, the capillary 81 is sequentially pressed against areas of the first strip portion 261 and the second strip portion 262 of the relay terminal 26 that overlap with the two conductive members 20, so that a plurality of first bonding marks 265 are formed on the first strip portion 261 and the second strip portion 262. When the first bonding marks 265 are formed, the capillary 81 and the clamp 82 are moved to predetermined positions. In the case of the semiconductor device A20, four first bonding marks 265 are formed. As shown in FIG. 27, the clamp 82 is not necessary when the fourth first bonding mark 265 is formed in the step of forming the first bonding marks 265.

Next, as shown in FIG. 28, the capillary 81 is placed to overlap with a first bonding mark 265, which is formed first among the first bonding marks 265, and is pressed against the first bonding mark 265, so that a second bonding mark 266 is formed on either the first strip portion 261 or the second strip portion 262 of the relay terminal 26. In this step, the capillary 81 is pressed across the periphery of the first bonding mark 265. Furthermore, the compression load applied to the capillary 81 when the first bonding mark 265 is formed is larger than the compression load applied to the capillary 81 when each of the other first bonding marks 265 is formed. This completes the first step.

The following describes advantages of the semiconductor device A20.

The semiconductor device A20 includes the relay terminals 26 each bonded to two conductive members 20 adjacent to each other in the first direction x. Each of the relay terminals 26 has a first strip portion 261, a second strip portion 262, and a connecting portion 263. The first strip portion 261 has a first side 261A. The connecting portion 263 has a first intermediate side 263A, and a first connecting side 263B connecting the first side 261A and the first intermediate side 263A. As viewed in the thickness direction z, the first connecting side 263B is located away from the first virtual intersection 268A that is the intersection of the first virtual line 267A overlapping with the first side 261A and the second virtual line 267B overlapping with the first intermediate side 263A. This allows the semiconductor device A20 to suppress cracks in the relay terminal 26 bonded to the two conductive members 20 during the manufacturing process of the semiconductor device A20.

The first strip portion 261 and the second strip portion 262 of the relay terminal 26 are formed with the bonding marks 264 overlapping with the two conductive members 20 as viewed in the thickness direction z. One of the bonding marks 264 includes the first region 264A and the second region 264B overlapping with the first region 264A. The second region 264B has the protrusion 264C located outward beyond the first region 264A. The protrusion 264C is a mark obtained by forming the second bonding mark 266 to overlap with a first bonding mark 265, which is formed first among the first bonding marks 265 in the first step described above with reference to FIGS. 24 to 28. This makes it possible to, when the relay terminal 26 is bonded to the two conductive members 20, reduce the total hours of ultrasonic vibrations given to the relay terminal 26, and bond the relay terminal 26 to the two conductive members 20 more firmly. This manufacturing method reduces the number of amplitudes of the repeated stress acting on the relay terminal 26, thus suppressing cracks formed in the relay terminal 26.

It is preferable that the protrusion 264C be located between the first region 264A and one of the bonding marks 264 that is located adjacent to the first region 264A in the first direction x. In this way, an end of either the first strip portion 261 or the second strip portion 262 of the relay terminal 26, which is an end on which the first region 264A and the second region 264B are formed, is bonded to one of the two first conductive members 20A more firmly. This prevents peeling up of the end.

The present disclosure is not limited to the above embodiments. Various design changes can be made to the specific configurations of the elements of the present disclosure.

The present disclosure includes embodiments described in the following clauses.

Clause 1.

A semiconductor device comprising:

two conductive members adjacent to each other in a first direction perpendicular to a thickness direction;

a semiconductor element bonded to one of the two conductive members; and

a relay terminal bonded to the two conductive members,

wherein the relay terminal has a first strip portion and a second strip portion that are bonded to the two conductive members, and a connecting portion that connects the first strip portion and the second strip portion,

the first strip portion and the second strip portion extend in the first direction, and are adjacent to each other in a second direction perpendicular to the thickness direction and the first direction,

the connecting portion is located between the first strip portion and the second strip portion in the second direction,

the first strip portion has a first side extending in the first direction,

the connecting portion has a first intermediate side extending in the second direction, and a first connecting side connecting the first side and the first intermediate side, and

as viewed in the thickness direction, the first connecting side is located away from a first virtual intersection that is an intersection of a first virtual line extending in the first direction and overlapping with the first side and a second virtual line extending in the second direction and overlapping with the first intermediate side.

Clause 2.

The semiconductor device according to clause 1, wherein the first connecting side forms a straight line.

Clause 3.

The semiconductor device according to clause 1, wherein the first connecting side forms a curve recessed toward an inside of the relay terminal as viewed in the thickness direction.

Clause 4.

The semiconductor device according to clause 3, wherein as viewed in the thickness direction, a part of the connecting portion is surrounded by the first connecting side, the first virtual line, and the second virtual line.

Clause 5.

The semiconductor device according to clause 3, wherein as viewed in the thickness direction, the first connecting side extends across the first virtual line and the second virtual line.

Clause 6.

The semiconductor device according to any of clauses 1 to 5,

wherein the second strip portion has a second side extending in the first direction and facing the first side,

the connecting portion has a second connecting side connecting the second side and the first intermediate side, and

as viewed in the thickness direction, the second connecting side is located away from a second virtual intersection that is an intersection of the second virtual line and a third virtual line extending in the first direction and overlapping with the second side.

Clause 7.

The semiconductor device according to clause 6,

wherein the first strip portion has a third side that is located opposite from the first side with the connecting portion therebetween in the first direction, and that overlaps with the first virtual line as viewed in the thickness direction,

the connecting portion has a second intermediate side that is located opposite from the first intermediate side in the first direction, and that extends in the second direction, and a third connecting side connecting the third side and the second intermediate side, and

as viewed in the thickness direction, the third connecting side is located away from a third virtual intersection that is an intersection of the first virtual line and a fourth virtual line extending in the second direction and overlapping with the second intermediate side.

Clause 8.

The semiconductor device according to clause 7,

wherein the second strip portion has a fourth side that is located opposite from the second side with the connecting portion therebetween in the first direction, and that overlaps with the third virtual line as viewed in the thickness direction,

the connecting portion has a fourth connecting side connecting the fourth side and the second intermediate side, and

as viewed in the thickness direction, the fourth connecting side is located away from a fourth virtual intersection that is an intersection of the third virtual line and the fourth virtual line.

Clause 9.

The semiconductor device according to any of clauses 1 to 8,

wherein the first strip portion and the second strip portion are formed with a plurality of bonding marks that each overlap with one of the two conductive members,

one of the plurality of bonding marks includes a first region and a second region overlapping with the first region, and

the second region has a protrusion located outward beyond the first region.

Clause 10.

The semiconductor device according to clause 9, wherein as viewed in the thickness direction, the first region and the second region are surrounded by a periphery of one of the two conductive members.

Clause 11.

The semiconductor device according to clause 10, wherein an area of the protrusion is smaller than an area of the first region.

Clause 12.

The semiconductor device according to clause 10 or 11, wherein the protrusion is located between the first region and one of the plurality of bonding marks that is located adjacent to the first region in the first direction.

Clause 13.

The semiconductor device according to any of clauses 1 to 12, wherein the relay terminal is thicker than each of the two conductive members.

Clause 14.

The semiconductor device according to any of clauses 1 to 13, further comprising two base members adjacent to each other in the first direction,

wherein the two conductive members are arranged on the two base members, respectively, and

as viewed in the thickness direction, the connecting portion overlaps with a gap provided between the two base members.

Clause 15.

The semiconductor device according to clause 14, further comprising a heat dissipator located opposite from the two conductive members with the two base members therebetween in the thickness direction,

wherein the two base members are supported by the heat dissipator.

Clause 16.

The semiconductor device according to clause 14 or 15, further comprising:

a first input terminal electrically connected to the two conductive members, and

a second input terminal,

wherein the first input terminal and the second input terminal are located in a first sense of the first direction and adjacent to each other in the second direction.

Clause 17.

The semiconductor device according to clause 16, further comprising an output terminal,

wherein the output terminal is located opposite from the first input terminal and the second input terminal with the two base members therebetween in the first direction.

Clause 18.

A method for manufacturing a semiconductor device, comprising the steps of:

bonding, with ultrasonic vibrations, a relay terminal to two conductive members adjacent to each other in a first direction perpendicular to the thickness direction; and

bonding a semiconductor element to one of the two conductive members,

wherein the relay terminal has a first strip portion and a second strip portion that extend in the first direction, and that are adjacent to each other in a second direction perpendicular to the thickness direction and the first direction, and a connecting portion that is located between the first strip portion and the second strip portion in the second direction, and that connects the first strip portion and the second strip portion,

the step of bonding the relay terminal includes a step of forming a plurality of first bonding marks on the first strip portion and the second strip portion by sequentially pressing a capillary against areas of the first strip portion and the second strip portion that overlap with the two conductive members as viewed in the thickness direction, and a step of forming a second bonding mark on either the first strip portion or the second strip portion by placing the capillary to overlap with a first bonding mark that is formed first among the plurality of first bonding marks and pressing the capillary against the first bonding mark, and

in the step of forming the second bonding mark, the capillary is pressed across a periphery of the first bonding mark.

Clause 19.

The method according to clause 18, wherein a compression load applied to the capillary when the second bonding mark is formed is larger than a compression load applied to the capillary when each of the first bonding marks is formed.

### REFERENCE NUMERALS

A10, A20: Semiconductor device
11: Base member
11A: First base member
11B: Second base member
111: Obverse surface
112: Reverse surface
12: Heat transfer member
13: Heat dissipator
131: Supporting hole
19: Adhesive layer
20: Conductive member
20A: First conductive member
20B: Second conductive member
20C: Third conductive member
21: First pad portion
22: Second pad portion
23: Third pad portion
24: Gate wiring line
24A: First gate wiring line
24B: Second gate wiring line
25: Detection wiring line
25A: First detection wiring line
25B: Second detection wiring line
26: Relay terminal
26A: First relay terminal
26B: Second relay terminal
26C: Third relay terminal
261: First strip portion
261A: First side
261B: Third side
262: Second strip portion
262A: Second side
262B: Fourth side
263: Connecting portion
263A: First intermediate side
263B: First connecting side
263C: Second connecting side
263D: Second intermediate side
263E: Third connecting side
263F: Fourth connecting side
264: Bonding mark
264A: First region
264B: Second region

### 264C: Protrusion

265: First bonding mark
266: Second bonding mark
267A: First virtual line
267B: Second virtual line
267C: Third virtual line
267D: Fourth virtual line
268A: First virtual intersection
268B: Second virtual intersection
268C: Third virtual intersection
268D: Fourth virtual intersection
27A: First conductive member
27B: Second conductive member

### 28: Pad

31: Semiconductor element
31A: First semiconductor element
31B: Second semiconductor element
311: First electrode
312: Second electrode
313: Gate electrode

### 32: Diode

321: Anode electrode
322: Cathode electrode

### 33: Thermistor

39: Conductive bonding layer
41: Input terminal
41A: First input terminal
41B: Second input terminal
411: Outer connecting portion
411A: Connecting hole
412: Inner connecting portion
413: Intermediate portion

### 413A: Base

413B: Upright portion
42: Output terminal
42A: First terminal portion
42B: Second terminal portion
421: Outer connecting portion
421A: Connecting hole
422: Inner connecting portion
423: Intermediate portion

### 423A: Base

423B: Upright portion
43: Gate terminal
43A: First gate terminal
43B: Second gate terminal
44: Detection terminal
44A: First detection terminal
44B: Second detection terminal
45: Input current detection terminal
46: Thermistor terminal
511-516: First wire to sixth wire
521: First gate wire
522: Second gate wire
531: First detection wire
532: Second detection wire
54: Input current detection wire
55: Thermistor wire

### 60: Case

611: First side wall
612: Second side wall

### 62: Mount

621: Mount hole
63: Input terminal block
631: First terminal block
632: Second terminal block

### 633: Groove

### 634: Nut

64: Output terminal block
641: First terminal block
642: Second terminal block

### 643: Groove

### 644: Nut

69: Top plate
71: Upper arm circuit
72: Lower arm circuit

### 81: Capillary

### 82: Clamp

z: Thickness direction
x: First direction
y: Second direction

1. A semiconductor device comprising:
two conductive members adjacent to each other in a first direction perpendicular to a thickness direction;
a semiconductor element bonded to one of the two conductive members; and
a relay terminal bonded to the two conductive members,
wherein the relay terminal has a first strip portion and a second strip portion that are bonded to the two conductive members, and a connecting portion that connects the first strip portion and the second strip portion,
the first strip portion and the second strip portion extend in the first direction, and are adjacent to each other in a second direction perpendicular to the thickness direction and the first direction,
the connecting portion is located between the first strip portion and the second strip portion in the second direction,
the first strip portion has a first side extending in the first direction,
the connecting portion has a first intermediate side extending in the second direction, and a first connecting side connecting the first side and the first intermediate side, and
as viewed in the thickness direction, the first connecting side is located away from a first virtual intersection that is an intersection of a first virtual line extending in the first direction and overlapping with the first side and a second virtual line extending in the second direction and overlapping with the first intermediate side.

2. The semiconductor device according to claim 1, wherein the first connecting side forms a straight line.

3. The semiconductor device according to claim 1, wherein the first connecting side forms a curve recessed toward an inside of the relay terminal as viewed in the thickness direction.

4. The semiconductor device according to claim 3, wherein as viewed in the thickness direction, a part of the connecting portion is surrounded by the first connecting side, the first virtual line, and the second virtual line.

5. The semiconductor device according to claim 3, wherein as viewed in the thickness direction, the first connecting side extends across the first virtual line and the second virtual line.

6. The semiconductor device according to claim 1,
wherein the second strip portion has a second side extending in the first direction and facing the first side,
the connecting portion has a second connecting side connecting the second side and the first intermediate side, and
as viewed in the thickness direction, the second connecting side is located away from a second virtual intersection that is an intersection of the second virtual line and a third virtual line extending in the first direction and overlapping with the second side.

7. The semiconductor device according to claim 6,
wherein the first strip portion has a third side that is located opposite from the first side with the connecting portion therebetween in the first direction, and that overlaps with the first virtual line as viewed in the thickness direction,
the connecting portion has a second intermediate side that is located opposite from the first intermediate side in the first direction, and that extends in the second direction, and a third connecting side connecting the third side and the second intermediate side, and
as viewed in the thickness direction, the third connecting side is located away from a third virtual intersection that is an intersection of the first virtual line and a fourth virtual line extending in the second direction and overlapping with the second intermediate side.

8. The semiconductor device according to claim 7,
wherein the second strip portion has a fourth side that is located opposite from the second side with the connecting portion therebetween in the first direction, and that overlaps with the third virtual line as viewed in the thickness direction,
the connecting portion has a fourth connecting side connecting the fourth side and the second intermediate side, and
as viewed in the thickness direction, the fourth connecting side is located away from a fourth virtual intersection that is an intersection of the third virtual line and the fourth virtual line.

9. The semiconductor device according to claim 1,
wherein the first strip portion and the second strip portion are formed with a plurality of bonding marks that each overlap with one of the two conductive members,
one of the plurality of bonding marks includes a first region and a second region overlapping with the first region, and
the second region has a protrusion located outward beyond the first region.

10. The semiconductor device according to claim 9, wherein as viewed in the thickness direction, the first region and the second region are surrounded by a periphery of one of the two conductive members.

11. The semiconductor device according to claim 10, wherein an area of the protrusion is smaller than an area of the first region.

12. The semiconductor device according to claim 10, wherein the protrusion is located between the first region and one of the plurality of bonding marks that is located adjacent to the first region in the first direction.

13. The semiconductor device according to claim 1, wherein the relay terminal is thicker than each of the two conductive members.

14. The semiconductor device according to claim 1, further comprising two base members adjacent to each other in the first direction,
wherein the two conductive members are arranged on the two base members, respectively, and
as viewed in the thickness direction, the connecting portion overlaps with a gap provided between the two base members.

15. The semiconductor device according to claim 14, further comprising a heat dissipator located opposite from the two conductive members with the two base members therebetween in the thickness direction,
wherein the two base members are supported by the heat dissipator.

16. The semiconductor device according to claim 14, further comprising:
a first input terminal electrically connected to the two conductive members, and
a second input terminal,
wherein the first input terminal and the second input terminal are located in a first sense of the first direction and adjacent to each other in the second direction.

17. The semiconductor device according to claim 16, further comprising an output terminal,
wherein the output terminal is located opposite from the first input terminal and the second input terminal with the two base members therebetween in the first direction.

18. A method for manufacturing a semiconductor device, comprising the steps of:
bonding, with ultrasonic vibrations, a relay terminal to two conductive members adjacent to each other in a first direction perpendicular to the thickness direction; and
bonding a semiconductor element to one of the two conductive members,
wherein the relay terminal has a first strip portion and a second strip portion that extend in the first direction, and that are adjacent to each other in a second direction perpendicular to the thickness direction and the first direction, and a connecting portion that is located between the first strip portion and the second strip portion in the second direction, and that connects the first strip portion and the second strip portion,
the step of bonding the relay terminal includes a step of forming a plurality of first bonding marks on the first strip portion and the second strip portion by sequentially pressing a capillary against areas of the first strip portion and the second strip portion that overlap with the two conductive members as viewed in the thickness direction, and a step of forming a second bonding mark on either the first strip portion or the second strip portion by placing the capillary to overlap with a first bonding mark that is formed first among the plurality of first bonding marks and pressing the capillary against the first bonding mark, and
in the step of forming the second bonding mark, the capillary is pressed across a periphery of the first bonding mark.

19. The method according to claim 18, wherein a compression load applied to the capillary when the second bonding mark is formed is larger than a compression load applied to the capillary when each of the first bonding marks is formed.
